(19) United States
(12) Patent Application Publication
(10) Pub. No.: US 2020/0083902 A1
(43) Pub. Date: Mar. 12, 2020

(54) METHOD FOR HANDLING MULTIDIMENSIONAL DATA

(71) Applicant: IDLETECHS AS, TRONDHEIM (NO)

(72) Inventors: Harald MARTENS, TRONDHEIM (NO); Hodjat RAHMATI, TRONDHEIM (NO); Jan Otto REBERG, TRONDHEIM (NO)

(73) Assignee: IDLETECHS AS, TRONDHEIM (NO)

(21) Appl. No.: 16/469,604

(22) PCT Filed: Dec. 13, 2017
(86) PCT No.: PCT/NO2017/050325

§ 371 Date: Jun. 13, 2019

Related U.S. Application Data
(60) Provisional application No. 62/433,715, filed on Dec. 13, 2016.

(51) Int. Cl. H03M 7/30; G06F 16/28; G06F 17/17; G06F 17/18; G06F 17/14

(52) U.S. Cl. CPC H03M 7/3059; G06F 16/283; G06K 9/6247; G06F 17/18; G06F 17/14; G06F 17/175

(57) ABSTRACT

Methods and corresponding apparatuses for compressing, monitoring, decompressing or analyzing multidimensional data in a computer system. A sequence of multidimensional input data is received from a data generating process and is processed by using an approximation model to project respective blocks of input data on a subspace. For each block of data, a residual representing the difference between said data block and a reconstruction of the data block from the projection of the data block on said subspace is calculated. The calculated residual is stored in a repository while the projection of the data block is appended to previously stored projections of data blocks in an output buffer. The approximation model may be extended through analysis of the repository of residuals in order to detect significant patterns. If a significant pattern is found, the pattern may be added as an extension to the approximation model. The extension to the model may be stored or transmitted as a transform packet which defines a transformation from an earlier model to the extended model.

### FIELD OF THE INVENTION

The present invention relates to a method for processing of massive amounts of data, such as more or less continuous streams of high-dimensional quantitative measurements. In particular, the invention relates to development of reduced-rank bilinear subspace models for purposes of analysis, compression and subsequent decompression of multidimensional data series, including monitoring and feature extraction.

### BACKGROUND

The need for analyzing massive amounts of data, and the ability to obtain such information, is increasing in most fields of endeavor. The development of small but sophisticated sensors, multichannel measurements, and the Internet of Things are among the drivers of this development, along with new methods for data mining in economic and social data.

Examples include spectrometers that are able to deliver hundreds of informative spectra per second. Hyperspectral cameras deliver multivariate spatially resolved images, and when these images are combined in time-lapse mode, the result is a continuous flow of high-dimensional spatiotemporal recordings. Spectrograms—i.e. high-dimensional frequency profiles from microphones, accelerometers, strain gauges and other types of mechanical force or vibration sensors, measured as functions of time, likewise provide streams of multichannel data. Similarly, large computer experiments can deliver outputs from thousands of simulations, each including thousands of input and output properties.

As a result, a measurement revolution is taking place in numerous fields as varied as analytical chemistry and medicine, mechanical engineering, environmental surveillance, and computer simulation studies, to mention but a few.

For safe and efficient utilization of such high-dimensional data streams it is desirable to automatically detect, quantify and compress the statistically valid variations in the data stream, rendering the information content of the data graphically interpretable and quantitatively useful in the compressed state.

The human ability to grasp information is limited by our perceptive and cognitive abilities, which are more or less constant. As such they are inadequate to the task of processing the vast amounts of data that are becoming available through large scale sensor arrays, data mining, the Internet of Things (IoT). In particular, beyond a certain scale it becomes impossible for a human to extract important data from insignificant or irrelevant data and noise.

Computerized methods for compressing and extracting information fall into two categories. The first category is based on a pre-existing theory for the system that is the origin of the data; data compression and processing is based on a model reflecting this theory. In order to be efficient, these methods demand that the system is well understood, that the model is adequate, and that the system does not deviate from the model over time except to the extent that the model is robust or able to adapt to such deviation.

The second category is based on the data as provided from the system and does not make any assumptions regarding the system itself. Instead the data is processed in order to discover redundancies and features in the data. This approach requires a vast amount of processing power and largely neglects efficiencies that can be obtained based on prior knowledge.

In addition to the respective shortcomings of the two categories, different fields of endeavor have different preferences and biases regarding them, based more on tradition than on their respective merits. As such, fields that traditionally work with well-established models of natural phenomena, such as physics, astronomy and the mechanical arts, tend to favor the former category, while fields that cannot rely on such models and fields that traditionally generate vast amounts of data, including chemistry, biology, social and psychological sciences and economics, generally favor the latter.

With respect to data compression there are two other categories to be considered: lossy compression and lossless compression. Lossless compression schemes reduce redundancies, but do not remove any information, and even the most insignificant information is restored when the compressed data is decompressed. Conversely, lossy compression in addition to removing redundancies filters out uninteresting noise and data that is considered insignificant with respect to a given purpose. This is used extensively and is well known in the fields of image compression (e.g. JPEG), video compression (e.g. MPEG) and audio compression (e.g. MP3). These forms of compression are highly efficient, but data is typically compressed differently for each data record, such that a full decompression is required before series of records can be assessed quantitatively, for example in graphical display, mathematical modeling or statistical testing.

Consequently there is a need for methods that allow compression, processing, analysis or monitoring of vast amounts of data, that benefit from—but do not depend on—prior knowledge or assumptions about the system producing the data, and that allow feature extraction, analysis and/or visualization of the data stream or changes in the data stream in a manner that is understandable to humans without producing information overload.

Subspace compression is a form of compression of multidimensional datasets through the reduction of dimensions. Thus, if the original dataset consists of K dimensions, a K-dimensional vector from the original dataset is represented by an A-dimensional vector in an A-dimensional subspace, where A<K.

In an example, k=1,2, . . . ,K represents the number of input channels recorded for each of i=1,2, . . . ,N samples, where N may, for example, represent N different experimental conditions, N points in time or N spatial locations. The K channels may e.g. be K wavelengths of light per pixel in a hyperspectral camera, K sensors monitoring a dynamic industrial process, or K points along a growth curve from a set of microbiological samples.Noise in such data is often random and uncorrelated between the K channels, but for electronic measurements such noise is usually just a small fraction of the signal. The important information is usually intercorrelated between many channels over the experimental conditions. This is true for the patterns of colored noise (systematic errors of various kinds in data, such as undesired interferants, temperature effects etc.) as well as for the signal patterns from the desired constituents (such as the presence of chemical analytes, and known design factors). Multivariate calibration has shown that desired and undesired phenomena in data can be equally important, especially if they overlap.

Sometimes some of the A subspace dimensions may be defined from prior knowledge in terms of expected variation patterns. For instance, for mixtures of chemical constituents, the pure spectra of known constituents may be used for resolving mixtures of them by some variant of direct unmixing. If many (J) similar, equally plausible analyte patterns are known, it may be useful to represent them by a reduced set of ≤J orthonormal basis vectors obtained by, for example, singular value decompositions (SVD) of these J pure component spectra.

However, in addition to expected analytes, more or less unanticipated chemical constituents and physical phenomena usually affect such measurements in practice. Information about these also needs to be retained. Identifying the remaining subspace dimensions therefore has to be data driven, at least to some degree. The subspace spanning the effects of unanticipated phenomena may be obtained by selecting A suitable subspace axes based on a set of empirically observed spectra. If pₐ is the profile (or “difference spectrum” or “direction”) defining axis dimension number a, the set of axis dimensions constitutes matrix P where columns are pₐ, a=1,2, . . . ,A. For computational purposes it is usually advantageous to define the axes to be orthonormal, so that P′P=I. The rank A and directions P (K x A) can easily be determined from N available empirical records, e.g. by SVD. But as long as new records arrive, N increases to a very high number. If unexpected new variation patterns arrive, it becomes critically important to be able to modify and extend A and P in a statistically valid and computationally efficient way.

Some methods depend on having all input data available in memory at all time. It is often desirable to avoid this dependency by making it possible to do the modeling in one pass through the input data.

### SUMMARY OF THE INVENTION

The present invention provides methods and apparatuses that address and alleviate some of the problems associated with existing solutions and provide a number of advantages.

According to a first aspect of the invention a method for compressing, monitoring or analyzing multidimensional data in a computer system is provided. The method includes receiving a sequence of multidimensional input data from a data generating process, processing the received input data by using an approximation model to project respective blocks of input data on a subspace, and for each block of data, calculating a residual representing the difference between the input data block and a reconstruction of the data block from the projection of the data block on the subspace. The calculated residual is stored in a repository of residuals, and the projection of the data block is appended to previously stored projections of data blocks in an output buffer. At predefined intervals the approximation model is extended by analyzing the repository of residuals to detect significant patterns, and if a significant pattern is found, including the pattern in the approximation model.

The intervals between extension of the approximation model may be one of predetermined regular time intervals, and based on an evaluation of at least one of the size and the variance of the repository of residuals.

In some embodiments it may be desirable to preprocess the input data prior to subjecting them to the approximation model. The preprocessing may include at least one of linearization, preliminary modeling and signal conditioning.

Statistical methods can be used to analyze the repository of residuals. In some embodiments this is done by performing at least one of principal component analysis (PCA) and singular value decomposition (SVD) on the data in the repository.

The approximation model and the projection on the subspace may constitute a bi-linear model where the approximation model is a matrix of loading vectors and the projection on the subspace is a score vector, with one loading vector and one score vector together comprising a factor.

In some embodiments a detected significant pattern is included in the approximation model by addition of a new loading to the approximation model, and distribution of new score components to the previously stored projections of data blocks. The distribution may be added in the output buffer before the output data is stored or transmitter for subsequent use. However, the new components may also be transmitted separately to be distributed to previously stored projections in a separate device or in permanent storage.

After one or more new loadings have been added to the approximation model, the approximation model may be updated through the performance of one or more of recentering, reweighting and reorthogonalization.

In embodiments of the invention where the approximation model and the projections (loadings and scores) are transmitted to be utilized elsewhere, it may become necessary to transmit information describing an extension or update of the approximation model as well. This may be performed by generation of a transform packet comprising at least one of a transform matrix representing an affine transform from an earlier point in time to a later point in time, and at least one new loading vector, a re-centering vector, and a re-weighting vector.

After one or more new loadings have been added to the approximation model, the approximation model may also be refined by removing loadings that are no longer considered significant.

The data received from a data generating process, may in various embodiments be data received from a plurality of sensors chosen from the group consisting of: spectrometers, hyperspectral cameras, infrared cameras, ultrasound sensors, microphone arrays, antenna arrays, radio telescope arrays and thermometers. However, the data may also be received from a repository of aggregated multidimensional data. The repository of aggregated data may, for example, be a repository of computer simulation results, social survey results, economical data and data extracted from network analysis.

In some embodiments the projected data blocks stored in the output buffer is forwarded to a display on a computer system. These data blocks may be preprocessed prior to this display, and may be accompanied by other parts of the approximation model.

The projected data blocks stored in the output buffer may be used, in the same device or subsequent to transmission to another device, to regenerate an approximation of the multidimensional input data.

In some embodiments the projected data blocks stored in the output buffer may be analyzed to generate a representation or an estimate of a feature of the data generating process. Again the analysis does not have to be performed while the data is stored in the output buffer, but may be performed subsequent to transmission or permanent storage.

According to a second aspect of the invention a method is provided for maintaining a bi-linear model constructed from a set of blocks of input data received by an encoder from a data generating process. The set of blocks is a set that increases in size as a result of repeated inclusion of additional blocks of input data received from the data generating process at points in time. The bi-linear model includes score vectors and loading vectors, with one loading vector and one score vector together comprising a factor. Reconstruction of data from the data generating process for one reconstruction point in time comprises the steps of for each factor, multiplying together the loading vector and one element of the score vector corresponding to the reconstruction point in time thereby forming a factor contribution, and adding together all factor contributions. The bi-linear model is updated based on receipt of a transform packet from the encoder. Thus reconstruction and model maintenance can be performed on the encoder which generates the model, and also on a different device from the encoder.

The transform packet may include a transform matrix representing an affine transform from an earlier point in time to a later point in time, and a at least one new loading vector.

The bi-linear model may further comprise a center vector.

In some embodiments the transform packets may include a re-centering vector.

In some embodiments the transform packet may include a re-weighting vector.

In some embodiments the transform packet has been generated by the encoder from a repository of a plurality of residual blocks. Each residual block has been generated as the difference between an input block and a reconstruction of the input block using the bi-linear model. The transform packet may include at least a new loading vector generated from statistical analysis of the repository.

The repository utilized by the encoder may comprise one least recent part comprising the least recent residual blocks and one most recent part comprising the most recent residual blocks. Loadings are based on both the parts. Subsequent to analysis the least recent part may be emptied and the most recent part may then become the least recent part.

Residuals to be included in the repository are in some embodiments selected or de-selected based on a criterion that can be one or more of a selected number of the latest residuals, residuals that are statistically significant, and residuals that have selected characteristics.

The statistical analysis may comprise at least one of Principal Component Analysis and Singular Value Decomposition.

In some embodiments outlier blocks are detected using leverage or residual variance in the statistical analysis. The outlier blocks may be modeled in a second-order repository.

In some embodiments loadings and scores may be rotated to optimize covariance or co-occurrence properties. This may, for example, be performed subsequent to extension of the bilinear model through addition of new loadings.

In some embodiments at least one of the factors can be deleted based on a criterion based on at least one of relevance, size, recency or memory availability.

Scores may be calculated based on loading weights.

In some embodiments the two-way model comprising loadings and scores is modified into a three way model, such as nPLS or PARAFAC.

In some embodiments loadings and scores are combined in a non-linear way to provide a reconstruction.

The loadings and scores may also be postprocessed according to one or more of the following criteria:
1) Independent Component Analysis (ICA),
2) Multivariate Curve Resolution (MCR), or
3) Optimization of entropy properties, non-negativity or unimodality.

In some embodiments at least one score is used for automatically controlling a process.

At least one part of one transform packet may be compressed using a data compression technique. The data compression technique may be a lossy technique that makes at least one transform packet become a changed packed, and the changed packet may be fed back to the encoder thus replacing the corresponding original part of the model.

According to another aspect of the invention a method for monitoring the state of a system is provided. A model is built according one of the aspects already described, and an alarm state is set based on score combinations that are not close to earlier observed score combinations, or based on residual variance exceeding a threshold.

Score combinations may be rotated to a common point in time.

According to yet another aspect of the invention a method is provided for predicting values of target variables that are known for certain points in time called training points and unknown for other points in time called prediction points, while other variables are continually known. According to the method a bi-linear model of the continually known variables is built according to one of the aspects already described. A prediction model is trained based on the training points, and predictions for the target variables at prediction points are estimated based on the prediction model.

In another aspect of the invention scores from two or more models are used as input blocks for another model.

In another aspect two or more bi-linear models are used, and for each input block or set of input blocks a decision is made regarding which model is to be updated based on each input block or set of input blocks, and the decision being made based on external measurements or metadata, clustering, or fit to each the model.

Blocks of input data may comprise physical measurements from a voltmeter, amperemeter, microphone, accelerometer, pressure sensor, RGB camera, thermal camera, hyper spectral camera, medical sensor, traffic sensor, magnetometer, gravimeter, chemical sensor or temperature sensor, or data originating from questionnaires, stock prices, word frequency counts in texts, statistical tables, medical measurements, data transmission measurements, production measurements or performance measurements.

According to another aspect of the invention a data encoder is provided using the method of any of the aspects described above for constructing a bi-linear model. The transform packets are stored on a storage medium or transmitted through a transmission channel, where it is accessible to a decoder separate in time or space from the encoder to reconstruct the model based on the transform packet.

According to yet another aspect a decoder using the method of any one of the previously described aspects to reconstruct an approximation of input data from the data generating process based on the bilinear model and the transform packet.

According to another aspect an apparatus for constructing and maintaining a bi-linear model of a set of blocks of input data that is increasing in size is provided. The increasing in size is caused by new blocks of data being included into the set of blocks of input data at points in time, the bi-linear model comprising score vectors and loading vectors, with one loading vector and one score vector together comprising a factor. A reconstruction of the data for one reconstruction point in time can be made by for each factor, multiplying together the loading vector and one element of the score vector corresponding to the reconstruction point in time thereby forming a factor contribution, and adding together all factor contributions. The bi-linear model is being updated based on transform packets by an encoder, each the transform packet comprises at least one of a transform matrix representing an affine transform from an earlier point in time to a later point in time, and a plurality of new loading vectors.

The apparatus may be configured to perform a method according to any one of the aspects described above.

The apparatus may be configured to use one or more of loadings, scores, center, weights, residuals or predictions to generate a representation on a display.

An apparatus according to this aspect may also be configured to use one or more of loadings, scores, center, weights or residuals in automatic control of a system.

An apparatus according to this aspect may be a decoder configured to reconstruct the model at different points in time.

Such a decoder may further use the reconstructed model to reconstruct an approximation of the input data.

According to yet another aspect of the invention a computer readable medium is provided. The computer readable medium is carrying computer executable instructions capable of enabling a processor to perform any one of the methods described above.

### BRIEF DESCRIPTION OF THE DRAWINGS

FIG. 1 is a conceptual illustration of a system operating in accordance with the principles of the invention.

FIG. 2 presents a more detailed view of a system operating in accordance with the invention and the associated data flow.

FIG. 3 is a flowchart illustrating various steps which may be employed in accordance with the invention.

FIG. 4 is a flowchart illustrating a preprocessing performed by a pre-treatment module in accordance with the invention.

FIG. 5 is a flowchart illustrating a decomposition (or approximation) and model expansion process in accordance with the invention.

FIG. 6 is a flowchart illustrating a model update process in accordance with the invention.

### DETAILED DESCRIPTION

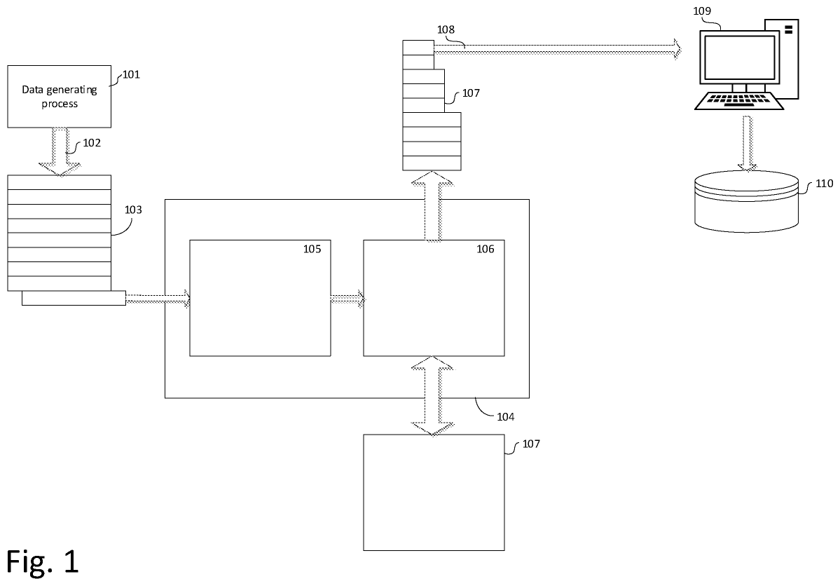

Reference is first made to FIG. 1 which is a conceptual illustration of a system operating in accordance with the principles of the invention. A data generating process 101 delivers a stream of raw data 102 to an input buffer 103. In this example it can be assumed that each sample is a vector representing K values from a corresponding number of sensors at a point in time. However, the samples (“records”) may equally well represent, for example, different experimental conditions (e.g. temperature) or spatial locations, or preprocessed data originating from only one sensor (e.g. sub-bands of an audio signal received from one microphone). The number of samples, N, may be fixed, but typically the process 101 is continually sampled and data will keep coming in at a steady rate, and be treated as a sequence of individual records or of batches of records. The number N will then grow correspondingly. The K different sensors may represent different wavelengths of light, levels of sound at different locations or in different sub-bands of an audio signal, etc.

The data in the input buffer 103 is organized in blocks, each including one or more samples, records, frames or objects. The blocks of multichannel data are transferred sequentially to a compression module 104. In the compression module 104 the data is first subject to pre-treatment, or preprocessing, in a pre-treatment module 105. The pre-treatment may include various mathematical operations and may vary in accordance with, for example, how much is known about the process 101 in advance. The preprocessing will be described in further detail below.

It should be noted that the module 104 by projecting the data on a subspace with a reduced number of dimensions inherently compresses the data. However, compression is not necessarily the only reason for utilizing the invention, and the use of the word compression herein is not intended to exclude embodiments that are primarily used for analysis or feature detection or alarm detection. The data may therefore also be referred to as modeled. Modeled data may include only the scores, or, in various embodiments, the scores and the loadings, or scores, loadings, preprocessing parameters as well as error residuals.

The preprocessed data is forwarded to an approximation stage 106 which compresses the data mathematically by reducing redundancy and replacing the high number of input variables with a comparatively low number of essential component variables that summarize the input data. The approximation stage will then produce modeled data 107 as its output. Based on the scores 107 and the loadings in the approximation stage 106 it will at any time be possible to reproduce the original data to a high degree. By inverting the invertible preprocessing, even the raw input data may be reconstructed with corresponding fidelity.

As will be described in further detail below, the approximation model—or the state of the approximation stage 106—may start out empty. It will then grow by recognizing systematic patterns of variation in the input data, while measurement errors and other non-systematic variation in the input data may be eliminated as statistical waste. This model expansion may be handled internally in the approximation stage 106, or it may be handled in a model expansion and update module 107.

It will be realized that the approximation model will grow whenever new systematic patterns are discovered. In the embodiment described above, this is a one way process, which does not reduce the size of the model when systematic patterns cease to occur, for example as a result of a change in the state of the data generating process 101. However, in accordance with certain aspects of the invention that will be described in further detail below, the model may be reweighted and updated (expanded, reorthogonalized and refined) at regular intervals or upon the occurrence of specific criteria.

The modeled data 107, which will be referred to as a set of score vectors, may now be transferred as a data stream over a data channel to a computer system 109 where the data can be stored or utilized. Also, data representative of the approximation model as well as parameters used during pre-processing in the pre-treatment module 105, may be transferred to the computer system 109 in addition to, or even instead of, the modeled data 107.

The computer system 109 may be the same computer system which implements the compression module 104, in which case the data channel 108 is one or more internal system buses in the computer system 109. However, the computer system 109 may also be a remote system, in which case the data channel 108 may be a connection over one or more computer networks or other forms of wired or wireless communication links.

The computer system 109 may utilize the received data stream in a number of ways, including visualization and analysis, depending on the use case scenario. In some cases the compressed data may be used directly, for example in order to create a visual representation of the data generating process 101 on a display of the computer system 109. The compressed data may also be decompressed, or decoded, by reversing the compression performed in the approximation stage 106, and, if it is desirable to obtain an approximation of the original raw data, the inverse of the pre-processing performed in the pre-treatment module 105 may also be performed. Visualization, analysis or any other desirable processing may then be performed on the decompressed data.

Finally, the data may be stored in a database 110.

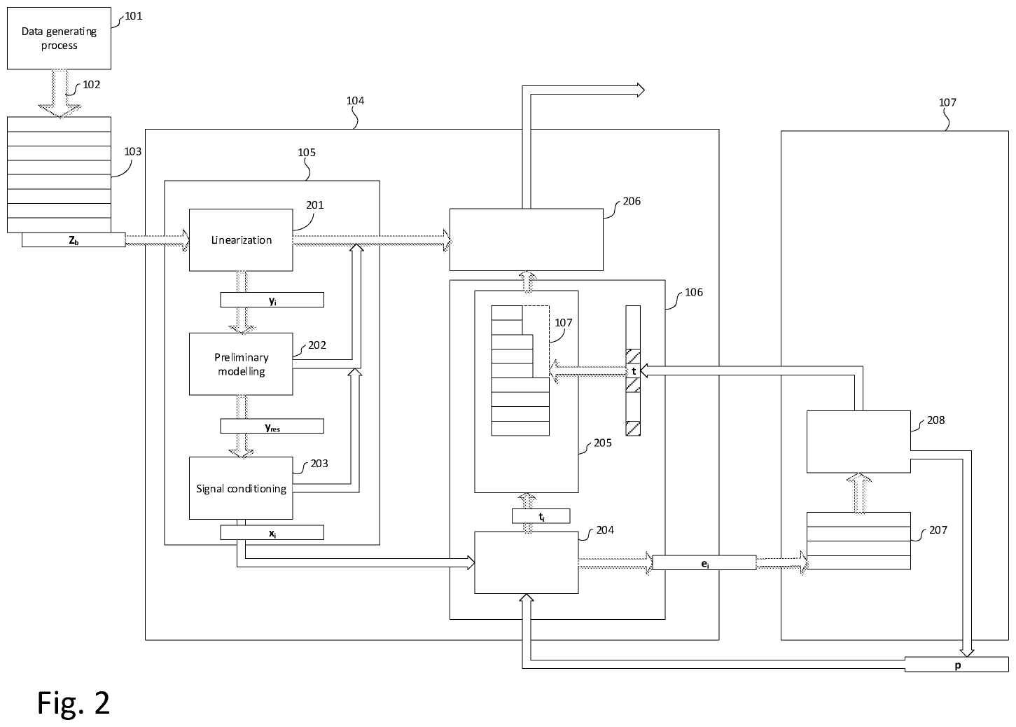

Reference is now made to FIG. 2, which presents a more detailed view of a system operating in accordance with the invention and the associated data flow. Elements corresponding to those illustrated in FIG. 1 are given the same reference number. It should be noted that this exemplary embodiment includes a number of features that are not strictly necessary in all embodiments, and their inclusion here should not be construed as a limitation on the scope of the invention, which includes numerous variations on exactly which steps or modules are included, as well as the sequence in which they are performed or how they are configured to interact.

Data is received from a data generating process 101 as an incoming data stream 102 and stored in an input buffer 103 as described above. Blocks of data are then transferred to the pre-treatment module 105 in the compression module 104 as a matrix Z_{b} which includes N_{b} rows of input vectors z₁ (i=1,2, . . . ,N_{b}). (N_{b} may, of course, be 1, in which case Z_{b} is a vector.) Pre-treatment may include different types of processing, and may consist of different modules, depending on the needs of a particular situation—for example on the properties of the input data. The pre-treatment module may be implemented in hardware, as a combination of hardware and software, or as a pure software module executed by one or more processors on a computer or a computing device. Furthermore, the pre-treatment module 104 may include one or more processing modules, which again may be implemented in hardware, software or as a hardware/software combination, and each processing module may execute one or more of the processing methods or routines which will be discussed in greater detail below.

In the example illustrated in FIG. 2 the pre-treatment module 105 includes three pre-processing modules, a linearization module 201, a preliminary modeling module 202 and a signal conditioning module 203. The input block Z_{b} is received by the linearization module 201. The linearization module 201 performs an invertibleprocess of modifying the raw data for improved response linearization, i.e. to turn non-additive variations in the raw data into linear (additive) phenomena in the pre-processed data. For example, in hyperspectral video, the linearization process could include a logarithmic response linearization, a model based separation of multiplicative light scattering effects from additive absorbance effects, and a correction for motion patterns by motion estimation and motion compression.

If necessary, the linearization process may include removal of some non-additive phenomena (for example, light scattering variations and motions) and represent them as additional variables, in which case the result will be a final set of K₊ variables, where K₊ is a number larger than the number of input variables Kᵢₙₚᵤₜ in the raw data. However, in order not to clutter this description with an unnecessary amount of variables with different indices, this description will continue to refer to the number of variables as K, which is intended to apply to the number of variables both with and without inclusion of additional variables, except if otherwise noted or indicated by the use of indices.

It should also be noted that while input block Z_{b} is described as a matrix, the following description of subsequent data processing will describe the processing of vectors (corresponding to rows of the input block matrix.) However, the skilled person will realize that also the subsequent steps could process the incoming data as matrices.

After the linearization stage 201 each input vector z₁ (1×Kᵢₙₚᵤₜ) has been transformed into a new vector yᵢ (1×K₊).

Parameters resulting from the linearization process may be transferred to an input/output buffer 206.

The linearized data may then be submitted to some sort of preliminary modeling in order to quantify and subtract already known phenomena. The preliminary modeling may be performed by preliminary modeling module 202, and will be described in further detail below. The purpose of the preliminary modeling is to remove data that can be quantified by a model of already known phenomena. The model can be used to estimate the contributions to the data from the known phenomena and to predict such contributions. Data extracted in the preliminary modeling process can be transferred directly to the input/output module 206, while the residual yᵣₑₛ, i.e. the data remaining after the modeled data has been subtracted from the linearized input data may then be processed further.

For optimal subsequent data approximation the linearized input data is then forwarded to a signal conditioning module 203, where the K variables in yᵣₑₛ are centered and weighted, as explained in further detail below. Again, the resulting parameters may be forwarded directly to the input/output module 206.

The vector xᵢ resulting from the signal conditioning may be delivered as input to the approximation stage 106.

In the approximation stage 106 each long data vector xᵢ (1×K) is subject to a compression process in a decomposition module 204, resulting in the shorter score vector t₁ (1×A). The decomposition module 204 performs compression by approximating xᵢ by tᵢ=f(xᵢ, P_{w}), where P_{w} (K×A) represents the so-called “loading weights” defining how to combine xᵢ into t₁. Data vector xᵢ is, in turn, approximated a function of score vector tᵢ by xᵢ=g(tᵢ)*P′+eᵢ, where P (K×A) is the so-called “loadings” and eᵢ (1×K) are the residuals. In the linear case, the scores are obtained by projection on an orthonormal loading weight matrix tᵢ=xᵢ*P_{w}, and the approximation model is xᵢ=tᵢ*P′+eᵢ, in analogy to the Partial Least Squares Regression, sparse PLSR and/or PLSR with discretized regressors. These methods can be found in Wold, S., Martens, H. and Wold, H.: The Multivariate Calibration Problem in Chemistry solved by the PLS Method. Proc. Conf. Matrix Pencils, (A. Ruhe and B. Kågström, eds.), March 1982, Lecture Notes in Mathematics, Springer Verlag, Heidelberg, pages 286 293 for a description of Partial Least Squares Regression, which is hereby included by reference.

A discussion of sparse bilinear modelling can be found in Liland, K. H., Hoy, M., Martens, H. and Sæbø, S: Distribution based truncation for variable selection in subspace methods for multivariate regression, March 2013, Chemometrics and Intelligent Laboratory Systems, 122, 15, Pages 103-111 (http://dx.doi.org/10.1016/j.chemolab.2013.01.008), which is hereby included by reference.

For bilinear modelling with discretized input variables, reference is made to Harald Martens: Non-linear multivariate dynamics modelled by PLSR. Proceedings of the 6th International Conference on Partial Least Squares and Related Methods, Beijing 4-7 2009 (V. E.Vinzi, M. Tenenhaus and R. Guan, eds), Publishing House of Electronics . http://www.phei.com.cn, p. 139-144), which is hereby included by reference.

For hierarchical cluster-based bilinear modelling, see Tøndel Kl, Indahl U G, Gjuvsland A B, Vik J O, Hunter P, Omholt S W, Martens H (2011) Hierarchical cluster-based partial least squares regression (HC-PLSR) is an efficient tool for metamodelling of nonlinear dynamic models.BMC Syst Biol. 2011 Jun. 1; 5:90. doi:10.1186/1752-0509-5-90, which is hereby included by reference.

For bilinear modelling with nonlinear inner relationships, see Tim Wul, Harald Martens, Peter Hunter and Kumar Mithraratne (2014) Emulating facial biomechanics using multivariate partial least squares surrogate models. INTERNATIONAL JOURNAL FOR NUMERICAL METHODS IN BIOMEDICAL ENGINEERING. Int. J. Numer. Meth. Biomed. Engng. (2014). Published online in Wiley Online Library (wileyonlinelibrary.com). DOI: 10.1002/cnm.2646, which is hereby included by reference.

For multi-linear modelling modelling of multi-way input data, where the individual input records xi do not represent vectors, but matrices or higher-way arrays, a reference is made to Kristin Tøndel, Ulf G. Indahl, Arne B. Gjuvsland, Stig W. Omholt and Harald Martens (2012) Multi-way metamodelling facilitates insight into the complex input-output maps of nonlinear dynamic models. BMC Systems Biology 2012, 6:88 doi:10.1186/1752-0509-6-88, which is hereby included by reference.

For bilinear modelling of a stream of input variables, the loading weights or loadings in the bilinear model may be filtered in terms of background information of some or all of these variables, e.g. a large data based of previous observations or theoretically conceivable components. A reference for this is L-PLS regression, given by Harald Martens, Endre Anderssen, Arnar Flatberg, Lars Halvor Gidskehaug, Martin Hoy, Frank Westad, Anette Thybo and Magni Martens (2003) : Regression of a data matrix on descriptors of both its rows and of its columns via latent variables: L-PLSR. Computational Statistics & Data Analysis, Volume 48, Issue 1, 1 Jan. 2005, Pages 103-123, and by its generalisation, Domino-PLS, in Harald Martens (2005) Domino PLS: A framework for multi-directional path modelling. Proc. PLS'05 Intl Symposium “PLS and related methods”. (Eds. Aluja, T., Casanovas, J., Vinzi, V. E., Morineau, A., Tenenhaus, M.) SPAD Groupe Test&Go), pp125-132, which is hereby included by reference.

These publications are hereby incorporated by reference in their entirety.

In the simplest linear case, the loading weights and the loadings are the same, P_{w}=P, in analogy to the Principal Component Analysis (PCA). This version will be used in the present system outline.

For efficient modelling of datasets where nonlinear relationships between the input variables have not (yet) been corrected, nonlinear extensions of the above-mentioned methods may be used. Such nonlinear relationships include curved relationships, mixed multiplicative/additive relationships, heterogeneous systems with very different types of relationships in different parts of the input variable space, etc. In such cases, function f(xᵢ, P_{w}) and/or g(tᵢ) could be formulated as nonlinear functions. with loadings weights and loadings estimated by the bilinear PCA or PLSR-like methods mentioned above. In the simplest case of mild response curvature, a polynomial extension of the centered input vector xᵢ, e.g. [xᵢ, xᵢ*x_{i,k}, k=1,2, . . . ,K] may be used as new input. On the other extreme, the bilinear model may be modified with a nominal-level expansion of input vector xᵢ, as described e.g. in Harald Martens (2009) Nonlinear multivariate dynamics modelled by PLSR. Proceedings of the 6^{th} International Conference on Partial Least Squares and Related Methods, Beijing 4-7 2009 (V. E. Vinzi, M. Tenenhaus and R. Guan, eds), Publishing House of Electronics Industry, http://www.phei.com.cn, p. 139-144 and multi-resolution extensions of this, and/or versions with higher-order nominal interactions, combined with sparse PCA (P_{w} being sparse, P being full) or PLSR (see above). In between, bilinear modelling with nonlinear inner relationships (see Wu et al. above) or hierarchical local modelling (see Tøndel et al 2011) may also be used in the bilinear modelling based on one-block PCA or two-block PLSR data modelling.

For multi-way input data, N-way bilinear modelling such as Parafac (http://www.models.life.ku/dk/˜ramus/presentations/parafac_tutorial/paraf.htm), N-PLS (see e.g. Tøndel et al 2012) and extensions thereof may be used. For instance, this may be obtained by unfolding each multi-way input data arrays into a 1-way vector, followed by conventional processing as described for one-way data, but with the following modification: Each loading weight estimate in Pw is forced to satisfy a low-rank multi-way criterium, e.g. by refolding it to a 2-way matrix, approximating this refolded matrix by bilinear (PCA) analysis, low-rank reconstruction of the 2-way matrix, unfolding the reconstructed loading weight matrix to 1-way vector, and finally re-orthogonalizing it relative to previous loading weights.

The score vector t₁ is delivered to an output buffer 205 where it is appended to previously stored score vectors, creating the score matrix T 107. Those with skill in the art will realize that the output buffer may be replaced by a process of directly writing the compressed data to storage, or streaming the data over a computer network to be stored or utilized elsewhere, as represented by input/output module 206.

When the loading weights and the loadings are the same, the loading matrix P is represented as an orthonormal loading matrix where P′P=I.

If the loading weights and the loadings are chosen to be different, then the loading weights P_{w} may e.g. be obtained by PLSR between two or more blocks of variables, or by PCA of one block of variables, but modified to be sparse, smoothed or otherwise modified, and then redefined to be orthonormal. In this case the loadings P may be non-orthogonal, because they are simply defined by projection of the input variables X on scores T by an updating version of the least squares expression P=X′*T*inv(T′*T). This requires an updating of not only T′*T, but also of matrix XT=X′*T. The latter may be maintained by the accumulation XT=XT+xᵢ*tᵢ, i=1,2, . . . where XT has been modified according to the previous model rotations and model translations.

The initialization of the loading matrix P and subsequent update will be described in further detail below. The update is based on an examination of unmodeled residuals, which are defined as the difference between the input data vector xᵢ and the result of the projection. The result is stored in a repository 207. However, in some embodiments values that are considered to be too small may be discarded immediately, rather than being stored in the repository 207. The threshold for considering the value of a residual eᵢ large enough to be considered for inclusion in the repository 207 may depend on the desired accuracy of the model.

Having a repository of residuals ensures a statistically stabilized system model development, with the ability to self-optimize. By basing the estimation of new potential model loadings on the residuals from many records (e.g. many points in time), the statistical precision of the loadings increases. In addition, by postponing the decision of whether or not to accept such a new loading estimate into the evolving system model till many records have been assessed, the decision becomes more precise, in the sense of “statistical significance: lower risk of accepting nonsense vectors and in the sense of “statistical power”: lower risk of overlooking real, but yet unmodeled variation types.

At regular intervals, or when the size or variance of R becomes too big (as deteimined by some predefined criteria), or if there is a significant pattern in the data, the repository is subjected to data decomposition in the decomposition module 208 that can for example be a PCA decomposition. If a number of observations of the same unmodeled phenomenon have ended up in R, the PCA will give a statistically stable estimate of this phenomenon in terms of a new loading p (i.e. a new column which can be added to P) and its corresponding score vector for the objects in R, which can be distributed back to T in the output buffer 107. R is then updated to remove the information that has now been included in T. The process of updating R will be discussed in further detail below.

As a result of the model expansion process described above, or changes in the data generating process 101 itself, it may be considered necessary (or at least advantageous) to update the model. This updating will be described in detail below, but generally falls into three categories. First, the variables in the model may be reweighted if imbalanced, i.e. if new observations have changed their relative variances rendering them imbalanced with the previous weighting c₀, or recentered if the previous model center x₀ gives too high bias, i.e. if the average output over time differs significantly from zero. Secondly, the model may be subject to reorthogonalization of the loadings P (or loading weights, if used) and/or the scores T (zeroing their sum vector sT and diagonalizing their cross product sum CT). And finally, certain (usually small) model components may be deleted if the model has developed too many components, or if the reorthogonalization process has isolated previous model noise contributions in separate, identifiable components. The parameters of the algebraic transform relating the previous model representation to the updated model representation can be stored at chosen intervals along with the other model parameters (c₀, x₀, P etc. as well as the latest block of scores), to allow all previously stored model scores T to be transformed to be compatible with the updated model parameters.

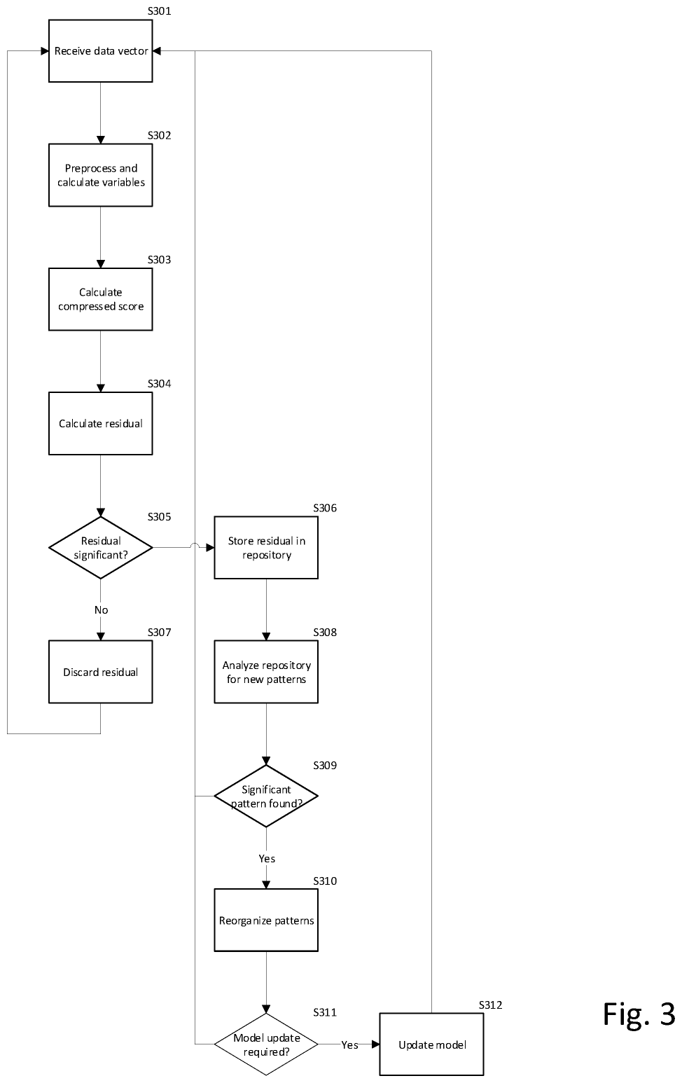

Reference is now made to FIG. 3, which summarizes the various steps described above in the form of a flowchart.

In a first step S301, a data vector is received from the data generating process 101. In a following step S302 the data input, in the form of a block Z_{b} or, alternatively, a single vector zᵢ is subject to preprocessing and variables (preprocessing parameters) are calculated in a pre-treatment module 105. The preprocessing may include linearization, preliminary modeling and signal conditioning, as described above.

In step S303 the preprocessed input is subject to decomposition in a decomposition module 204. After the data has been decomposed, the residual is calculated in step S304. As explained above, the residual is the difference between the original (preprocessed) data input and the decompressed result of the decomposition. It may then be determined in step S305 whether this residual is sufficiently large to be stored in a repository of residuals in step S306. Of course, this step may be omitted, in which case all residuals are stored in the repository. If the residual is determined to be insignificant, the unmodeled residual is simply discarded in step S307 and the process returns to step S301.

After the residual has been stored in the repository, the repository is analyzed for new patterns in step S308. It should be noted that this is normally not a process that happens after every single instance of a residual vector being written to the repository. Instead, the process may return to step S301 repeatedly until it is determined by some criteria that the repository should be analyzed. (Indeed, many of the processes included in this flowchart may run in parallel, and may not have to wait for each other to complete as long as they have the necessary data available to proceed.)

In step S309 it is determined whether the analysis of the repository resulted in the discovery of one or more significant new patterns. If not, the process again returns to step S301. If, however, a significant pattern is found, the patterns are reorganized in step S310. Step S310 primarily comprises the inclusion of a new vector p to the compression model matrix P and the distribution of scores back to the previously compressed data in accordance with the expanded model. The determination may be made using principal component analysis (PCA) of the data stored in the repository, and the new patterns will be the resulting principal components.

After the model has been expanded through reorganization of patterns in step S310 it may be determined in step S311 whether it is necessary to update the model. If this is not the case, the process returns to step S301. If model update is considered necessary or preferable (or is otherwise scheduled to be performed) the process continues to step S312 where the model is updated before returning to step S301. (Again it should be noted that the model update steps do not have to follow directly after each instance of model expansion, and that the principle that as long as the processes have the necessary data to process, they may run independently or in parallel.)

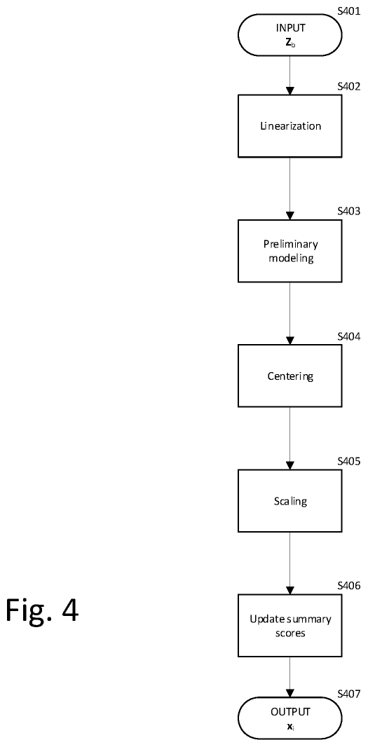

Having thus provided a general overview of the whole process according to the invention, reference is now made to FIG. 4, which illustrates the preprocessing performed by the pre-treatment module in further detail. The steps illustrated in FIG. 4 substantially correspond to steps S301 and S302 in FIG. 3.

In the first step S401 a block of data Z_{b} (or a data vector zᵢ) is received from the input buffer 103. The input data is then subject to linearization in step S402. As those with skill in the art will realize, the linearization process will depend on the properties of the input data. As mentioned above, the linearization process may, for example, include logarithmic response linearization, model based separation of multiplicative effects from additive effects, and correction for motion patterns by motion estimation and compensation. Some nonlinear phenomena may be detectable in a higher-dimensional space, which will increase the dimensions of the data block. Thus, if a row of input data is the vector zᵢ with dimension 1×K, the linearized vector yᵢ will be a vector with dimension 1×K₊. For simplicity, however, the dimensions of the uncompressed data will be referred to as K throughout this discussion. IDLE-based motion estimation and motion compensation modelling (Martens 2015) may likewise quantify and correct for displacements in video data.

For optimal bilinear modelling, well understood types of nonlinearities may be reduced in a preprocessing stage. For instance, model-based pre-treatment, such as Standard Normal Variate (SNV), Multiplicative Scatter Correction and Extended Multiplicative Signal Correction (EMSC), can be used to separate multiplicative effects from additive effects in spectra.

Following the linearization step, the linearized data may be further processed in a preliminary modeling step S403. The preliminary modeling step may be performed by preliminary modeling module 202 and may again depend on the properties of the data generating process and the extent to which this is known. By way of example, the preliminary modeling may include a linear mixture model with known constituents, for example known spectra S (K×nS, where nS is the number of known constituents).

A block of linearized input vectors Y may then be expressed as

Y=CS′+Yᵣₑₛ

where Y is a block of linearized input vectors yᵢ, C represents the magnitude or contributions of the known constituents, in an example this may be concentrations of respective known constituents, and Yᵣₑₛ is the residual, i.e. the contributions to Y that are not from the known constituents.

This modeling step may be used for estimating the concentrations Cₑₛₜ of the nS known constituents, for example by weighted least squares regression of each row in Y on S over the K channels. In other words, the concentrations of the known constituents for one input vector yᵢ (a single row in Y) are estimated to be those that minimize the vector y_{res,i} (the corresponding row in Yᵣₑₛ).

The residuals may then be computed as

Yᵣₑₛ=Y−CₑₛₜS.

Additionally, a calibration model may be used for predicting concentrations, for example by the linear predictor from present and past Y-variables via calibration model

C_{pred}=YB

where B is a regression coefficient

B=S(S′S)⁻¹.

The estimated concentrations Cₑₛₜ and predicted states C_{pred} can be saved as compressed representations of information known a priori to be interesting. The unmodeled residuals Yᵣₑₛ may then replace the original variables in Y. (Again, in order to reduce the number of variables with indices, and since the preliminary modeling step is optional and may not be used in all cases, the index “res” will not be included in the following description.)

As mentioned, the preliminary modeling described above is optional and in some embodiments of the invention, step S403 may be omitted. The utility of the preliminary modeling depends, of course, upon the amount of information about the data generating process 101 that can be used to create the mixture model. If the magnitude of Yᵣₑₛ is not significantly smaller than the magnitude of Y, preliminary modeling might not be worthwhile.

For optimal data processing in the approximation stage 106, e.g. in order to facilitate an efficient generalized Taylor expansion and also facilitate better balance of the variables' variances, the input data may then be subject to a centering and scaling process steps S404 and S405, respectively. In which a common model mean y₀ is subtracted from the input vector yᵢ and the result may then be weighted by a weighting vector c₀. Taken together these steps may be expressed as

xᵢ=(yᵢ−y₀)*c₀

where * denotes element by element multiplication. For each variable k=1,2, . . . ,K this may be written

xᵢₖ=(yᵢₖ−y₀ₖ)·c₀ₖ.

The vector y₀ acts like expansion point in Taylor expansion; as it is preferable to do Taylor expansion over different points depending on where in data we want to expand the model on, in the invention different y₀ can be set. It can be set to zero or other values depending on the application. Most commonly it is set to be the mean value of the data in order to exclude the mean value out of the model and simplifying it.

The vector weights c₀ has a more substantial effect on the model. It is used to weight different variables according to some criteria, e.g. if some prior knowledge of the data is available regarding the importance of different variables, the weights can be used to downweight the less important variables and to amplify the significant ones. Therefore, the significant variables are given more importance in developing the model. Common way is to set the weights to normalise variables with respect to their standard deviation, so the different variables are given equal importance in building the model.

Several normalization methods can be used in order to find the weighting vector c₀.

In some embodiments of the invention the weighting vector is found by standardization, wherein c₀=[c₀ₖ, k=1,2, . . . ,K] is defined as

c₀=1/std(Y),

i.e. as the inverse of the total standard deviations of the chosen set of objects, Yᵢₙᵢₜᵢₐₗ[yᵢ, i=1,2. . ., Nᵢₙᵢₜᵢₐₗ]. This weighting vector may be updated later on based on the structure in the input data or based on external information.

In other embodiments a pre-selected weighting where the vector c₀=[c₀ₖ, k=1,2, . . . ,K] is defined to have elements

c₀ₖ=relevance(k)/uncertainty(k)

wherein the values relevance(k) and uncertainty(k) are predefined by the user. The values may optionally be updated later based on new information from the data or from external sources.

Yet another alternative for finding or determining the weighting vector c₀ in embodiments of the invention is to use constant weighting, where the vector c₀=[c₀ₖ, k=1,2, . . . ,K] is simply defined as having all its components equal to 1,

c₀ₖ=1

for all k.

The unweighted model center y₀=[y₀ₖ, k=1,2, . . . ,K] is defined as the mean of the unweighted data:

y₀=mean(Y)

In a next step S406 the cumulative sum of the x-variables are updating by adding xᵢ to a cumulative sum sx (1×K) and a corresponding cumulative sum-of-squares of the x-variables, s2x (1×K) as follows

sx₁=sxᵢ₋₁+xᵢ, and

s2x₁=s2xᵢ₋₁+xᵢ².

These sums are not parts of the preprocessing as such, but they may be retained in memory and used to determine the weighting vector c₀, and/or whether it is necessary to update the model, as will be explained in further detail below.

The resulting pre-processed input vectors xᵢ (or preprocessed input blocks X_{b}) may then be forwarded to the approximation stage 106 in an output step S407. As part of the output step S407, preprocessing variables or parameters may be forwarded directly to the input/output buffer 206.

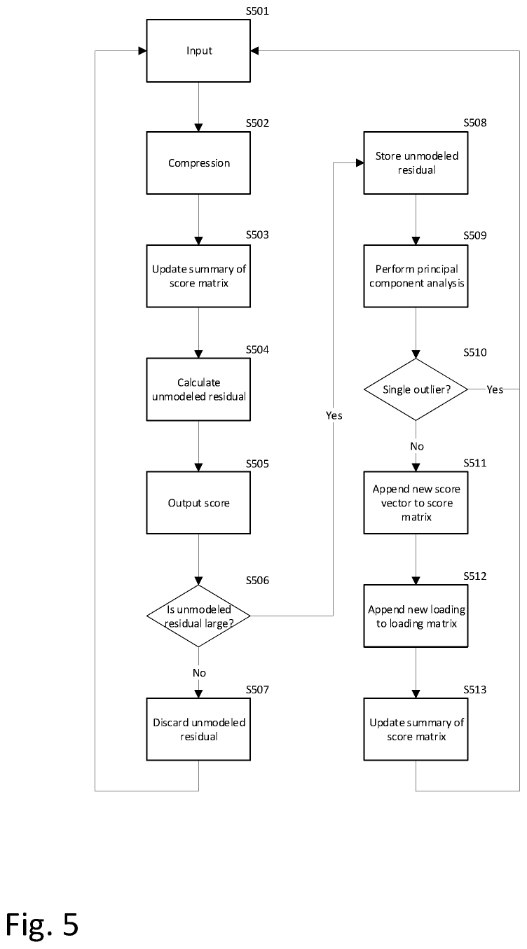

With reference to FIG. 5, the decomposition (or approximation) and model expansion process will now be explained in further detail. Again it should be emphasized that while the steps are described here as being performed sequentially, they may in principle be performed in parallel as long as the necessary data is available for performance of a particular step. The steps in FIG. 5 substantially correspond to steps S303-S310 of FIG. 3.

The process starts with step S501 when the approximation stage 106 receives the preprocessed input vector xᵢ. (Or input block X_{b}.)

In a following step S502 the input vector is decomposed. This is done by projecting each long data vector xᵢ with dimension 1×K on the loading matrix P. Initially the loading matrix P may be empty, or it may contain component loadings defined a priori or estimated in lab experiments. It should be noted that while this initialization may be based on a priori knowledge of the data generating process 101, it will typically not be the same information as the information used in the preliminary modeling step S403 of the pre-processing. The preliminary modeling step removes information from the input data and forwards this information separately as pre-processing parameters, and consequently the knowledge used in preliminary modeling does typically not extend to the data forwarded to the approximation stage 106.

As described above, the loading matrix P is orthonormal (if the reweighting is not considered), such that P′P=I.

The loading matrix P has A components (i.e. it is an K×A matrix) and the projection of xᵢ on P gives the shorter score vector tᵢ (1×A),

tᵢ=xᵢP(P′P)⁻¹.

The output from the compression process can be stored as a matrix T such that the score vector tᵢ is appended below the matrix of previous scores

Tᵢ=[T′ᵢ₋₁t′ᵢ]′,

where Tᵢ₋₁ is the score matrix prior to, and Tᵢ is the score matrix subsequent to the current score vector tᵢ being appended.

The score matrix will grow continuously and may become very big, so it may not be preferable to maintain T in computer memory (although keeping T in memory is, of course, consistent with the principles of the invention). However, knowledge of the score matrix may be required for model updating, as will be explained in further detail below, and to that end a summary of T may be created. In particular, a cumulative sum vector sT (1×A) and a cross-product matrix CT (A×A) may be maintained. These may be defined as

s_{T,i}=S_{T,i-1}+tᵢ, and

C_{T,i}=C_{T,i-1}+tᵢ′×tᵢ.

The calculation of S_{T} will, of course, be performed as repeated addition of each new tᵢ to the current sum vector. The matrix CT is similarly obtained through repeated addition of the matrix resulting from taking the cross product (or vector product) of each new t with itself and adding it to the previous such matrix.

The score vector tᵢ is also used to calculate the unmodeled residual in step S504. The unmodeled residual is calculated by decompressing the score vector by projecting it on the the loading matrix P and subtracting the result from the uncompressed vector,

eᵢ=xᵢ−tᵢP′.

After the summary vector and matrix have been updated and the unmodeled residual has been calculated, the score tᵢ may be delivered to output in step S505 either by writing it to disk or by transmitting it over a communication link to be further utilized elsewhere.

In embodiments where the repository only stores residuals that are larger than a certain threshold, the unmodeled residual e₁ is evaluated in step S506. If the unmodeled residual eᵢ is found to be too small to represent any significant unmodeled variance, it is simply discarded in step S507 and the process returns to step S501. If, however, the residual eᵢ is large enough, or for all residuals in embodiments without a threshold limitation, it is stored in a repository of unmodeled residuals 207 in computer memory in step S508. Prior to entering the new residuals to the repository, in order to make sure that every rows in the repository has been scaled with the same weights we make sure that the repository is scaled with the same weighting vector that is used for the new residuals. The unmodeled residuals may be stored as a matrix R with dimensions M×K, where M is the number of residuals that have been found large enough to be stored (M×N).

The objects in R may be identified by a time stamp or in some other manner that uniquely identifies the object and makes it possible to associate the object with a corresponding input vector xᵢ and output vector (or score vector) tᵢ. The time stamps may be stored along with the residuals in a table in computer memory, but it may be useful to make the time stamps available as a separate vector o_{R} with dimension (M×1). The subset of components in T that have a corresponding entry in R may then be represented as T_{R}=T(o_{R}). In other words, T_{R} represents the previously estimated scores from already established model components for the objects in o_{R}. In embodiments where all residuals are stored in R, T_{R}=T.

The process now moves on to step S509, where a decomposition (for example PCA, SVD, eigen decomposition) is performed in search for new components (or patterns) in R. It is not efficient to perform this search every time a new residual eᵢ is added to R. (As such, the process may return to step S501 to receive additional input before eventually performing this search.) Specific criteria may be defined for when a search should be performed, for example at regular intervals or when R reaches a predetermined size. These criteria may represent tuning parameters that may depend on the variance of the data generated by the data generating process 101, the rate at which these data are received, the size of K, the (current) size of A, available memory and computing power etc. They may therefore have to be determined in each particular case for different embodiments of the invention.

In the simple linear version of the invention, decomposition may be performed as singular value decomposition (SVD) or some other bilinear modeling algorithm:

R=US_{R}V′

The purpose of this analysis is to determine if one or more new components can be identified as significant in R. If a number of observations of the same unmodeled phenomenon have ended up in R, the PCA will give a statistically stable estimate of this phenomenon in terms of a new loading p, represented as a column of V, and its corresponding score vector, represented as a multiplication of the corresponding column of U multiplied by the corresponding singular value in S, for the objects in R.

SVD is well known in the art and will not be explained in detail herein. Suffice to say that V′ is a square, unitary matrix of dimension K×K, S_{R} is a diagonal matrix of dimension M×K, and U is an M×M unitary matrix. Simplified SVD is normally used, computing only the first few components. Whether one or more of these computed components are to be accepted as new model components depends on the acceptance criteria defined. These criteria may e.g. concern

the percentage variance or sum-of-squares in the input data that need to be modelled, or
the size of a PC's singular values
the significance of scores.

Thus the SVD model of R, with A(R) components, becomes

R=US_{R}V′+E_{A(R)}

where U is (M×A(R)), V is (K×A(R)) and S_{R} is (A(R)×A(R)), and A(R)<<min(M,K). For more on SVD, reference is made to standard textbooks on linear algebra.

In some embodiments each row of the repository is analysed against an outlier detection step S510. In which both the scores and the residuals outliers are detected. In either case the outlier objects are temporarily down-weighted in order to reduce their destructive effects on the model. If the same object has been detected as outlier again, it is considered as a definite outlier and it is completely removed from the repository and the model. Such outliers are sent to a repository of outliers, in which a thorough study of the outliers are applied in order to find categorical outlier that show significant information about the system. The temporary outliers may be given small weights wi <<1 and thus down-weighted in the SVD compared to the other rows in R, by defining sample weight vector w(M×1) as w=[1,1, . . . ,wᵢ,1, . . . 1]:

diag(w)*R=U_{W}S_{R}V′+E_{A(R),W}

with U=diag(w)⁻¹ U_{W} and E_{A(R)=diag(}w)⁻¹*E_{A(R),W}

If all potential components are eliminated or strongly down-weighted in this way, the process returns to step S501. Otherwise, if a new component explains enough sum-of-squares in R and/or otherwise satisfy the chosen acceptance criteria, the component is regarded as valid. Another way of checking the significance of a component is to compare the corresponding singular value with the prediction of that singular value from the smaller singular values, and if it is bigger than an uncertainty threshold above the predicted value, it is considered significant. An alternative criterion for determining whether a given component should be considered sufficiently significant for expansion of the model P is to consider the magnitude of the singular values in S and only include loadings p=v and corresponding scores t=us if the corresponding singular value s is above a chosen threshold, where the size of the threshold is selected based on the desired accuracy of the model. It is, of course, possible to implement both of these criteria, and remove outliers as well as components with small singular values. In other embodiments this step is omitted entirely, and all components resulting from the PCA are regarded as valid.

In an example, u₁ is the first column of U, S₁ is the first singular value on the diagonal of S, and v₁ is the first column of V. The new score vector t is found by considering

t_{R}=u₁s₁,

which is a vector of all the contributions to the new score vector t from the objects in R. In other words,

t_{R, A(R)=0}=t_{R}.

Thereby t is zero for all objects not present in R. In embodiments where all residuals are stored in R and none are discarded, all objects are, of course, present in R.

The scores produced by this new component are thus distributed back into a new column in T in the original sample order. It should be noted that the new score vector t is not a new row tᵢ in T. Instead, it is a column vector that contributes a new column to the matrix T (i.e. A is increased by 1). This is illustrated in FIG. 2 as vector t which is added to the compressed data 107 from the decomposition module 208. In other words, in a step S511, the vector t is appended beside the other component vectors of previous scores:

T_{New}=[T, t].

Likewise, the new loading p, which in this example is found as v₁, is appended to the established loading matrix P in a following step S512

P_{New}=[P, p].

This process is repeated for all components that have been identified as significant in the repository.

The process then moves on to step S513, where the score sum for the T matrix is updated. It should be easily realized that s_{T} can be updated simply by appending the sum of all the components in t as a new component in s_{T}, or

s_{TNew}=[s_{T}, 1′t],

where 1 is the vector with the same dimension as t (N×1) and all components equal to 1.

The cross product sum matrix CT may also be updated, as

C_{T,New}=[C_{T}T′t; t′T t′t].

Since the vector t is zero for objects not in R, this can be written

C_{T,New}=[C_{T}T_{R}′t_{R}; t_{R}′T_{R}t_{R}′t_{R}].

Therefore it is not necessary to keep all the old scores in T in memory, it is sufficient to keep T_{R}, which is the rows of previous scores correspondence with the objects in the repository.

As a result of adding the new score vector to T and the new loading vector to P the number of components is increased to A_{New}=A+1. If several new components have been identified, A is increased correspondingly. In this way the bilinear model grows in dimensionality from empty (unless the matrix P has been initialized with pre-known components). This is illustrated in FIG. 2 as a stepwise lengthening of the score vectors illustrated as stored in the output buffer 107. It should, however, be realized that whenever A is increased, all existing score vectors are expanded either with the scores from t_{R} or with zeros, so all vectors tᵢ in T will of course have the same length.

If the loading matrix P is initialized as an empty matrix, it will be realized that until decomposition is performed on the repository of residuals for the first time, all scores tᵢ will be zero and all residuals eᵢ will be equal to the input vector xᵢ. When decomposition is performed, the resulting score vector t for each identified component may, of course, include a non-zero value for any input vector going back to the very first input vector (provided that input vector has not been discarded from being placed in the repository or been removed from the repository for some reason).

After the model has been expanded in this way, the residuals stored in R must be correspondingly updated. This can be done by recalculating the unmodeled residuals using the same method as in step S504. However,

E_{New}=X−T_{New}P_{New}′=X−TP′−tp′=E−tp′.

In other words, it is not necessary to repeat any calculations that have already been performed. The resulting matrix of residuals, E_{New}, replaces the residuals that were used to expand the model. If a threshold is used to discard residuals that are considered too small to represent any significant unmodeled variance in step S507, that same threshold may be used to discard residuals in the new matrix E_{New} before it is stored in the repository as the updated matrix R.

The size of the repository will in principle keep growing, since one residual eᵢ is created for each input vector xᵢ. The size may be reduced somewhat by discarding residuals that are smaller than a predefined threshold—which may also cause removal of entries in R as a result of identification of new components, as described above. However, it may be necessary, or at least preferable, to limit the size of R. According to some embodiments of the invention the size of R is limited to a specific number of entries, for example representing a given period of time, and the repository R may simply be emptied after it has been analyzed using PCA. Another alternative is to use two time horizons. Whenever the repository R is full, the entries that are between the first and the second time horizon are deleted, while the entries that are younger than the first time horizon will remain in the repository until the next time horizon.

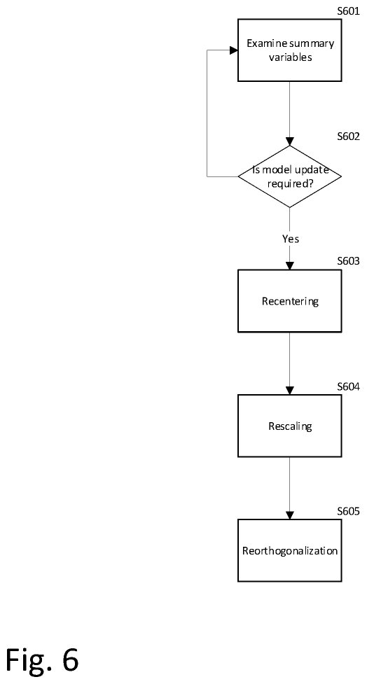

The model expansion process has now concluded and returns to step S501. However, over time it may become necessary to update the model in a process that in FIG. 3 is illustrated as process steps that follow sequentially after the model expansion, but which may in principle run in parallel with the pre-processing, compression and model expansion processes, as long as the necessary data and criteria for model update are available. The model update process will be explained with reference to FIG. 6.

At regular intervals, or if the conditioning of the data seems outdated, or if the model seems to have too high bias, or the scores and loading matrices deviate from orthogonality, or too many components, a model updating process may be performed.

Conditioning of the data can be determined by examining the summary sum sx. based on sx the new center for the data is calculated and if this deviates significantly from the previous center, which was used in modelling the data, the model needs to be updated with the new enter.

If the data is mean-centered prior to being modeled, the sum of scores sT must be zero. If sT deviates significantly from zero this indicates that it may be beneficial to update the model in order to correct for this bias.

In ideal case the scores and loadings matrices must be orthogonal matrices. However, due to rescaling the data, the orthogonality might fail, therefore the model needs to be updated with reorthogonalization.

If the model develops more components than wanted, or if one or more of the components are insignificant, model adjustment may be advantageous. A model adjustment may either transpose a component to a new space such that redundancy in the model is reduced, or some of the insignificant components may be removed.

The process of updating the model generally follows the steps illustrated in FIG. 6, which corresponds to the steps S311 and S312 in FIG. 3. The process commences in a first step S601 where the summary variables are examined. Based on the examination performed in step S601 it is determined in step S602 whether an update of the model is required. If not, the process returns to step S601 and performs a new examination of the summary variables. The examination of the summary variables may be performed regularly, or may be triggered by a specific condition.

If it is determined in step S602 that a model update is required, the process proceeds to step S603 where the model is recentered.

The unscaled mean of the modelled data is computed:

x₀=sx/N

The change in the unscaled model mean, dx₀ , is then computed f

dx₀=x_{0,old}−x₀

If dx₀ is not significant with respect to x_{0,old}, no update is applied on the centering, otherwise this difference dx₀ between the old and the new x₀ is scaled to the current scales and projected to the current loadings:

dx₀=dx₀*c₀

T_{add}=dx₀*(P^{T} P)⁻¹ P^{T}

dX_{0,res}=dX₀−T_{add}*P^{T}

The residual of this projection is normalized to length l:

t₀=sqrt(dX_{0,res}*dx_{0,res}^{T})

p₀=dx_{0,res}/t₀

To avoid maintaining the whole scores T in memory, it is instead appended to the statistical summaries sT and CT. Let Aₜ₋₁ be the number of components at the last model updating. Let Nₚ₋₁ be the number of rows in scores that exist in the memory currently as well as at the time that last model updating was applied, and let Nₚ be the total number of rows of scores that currently exist in the memory. If the center has change the following corrections is applied:

CT=CT₃+CT₂+CT₃^{T}+CT₄

CT₁=[CT 0 0 0]_{(A+1)*(A+1)%appended with zero because of the centering components}

CT₂=0_{(A+1)*(A+1)}

CT₂(1:A,;)=[sT^{T}*T_{add}, ST^{T}*t₀]

CT₃=N*[T_{add}^{T}*T_{add}, t₀*T_{add}^{T}t₀*T_{add}, t₀²]

The sum of rows sT is updated as follows:

sT=[ST+N*T_{add},N*t₀]

The centering components are append to the model components:

P=[P,p₀^{T}]

T=[T+1T_{add}, 1t₀]

A=A+1

After adding the centering components to the model, the process moves on to the reorthogonalization step S605 if scores and/or loadings significantly deviate from orthogonality. Reorthogonalization becomes necessary because the reweighting step described above has converted the previously orthonormal matrix P to a non-orthogonal matrix, and the same is the case with the score matrix T. The loading matrix P can be reorthogonalized by singular value decomposition:

P=U_{P}SₚVₚT

However, as described above, the whole T may not be stored in memory in order to avoid excessive memory and CPU load. The reorthogonalization of T may then be carried out by performing SVD on the CT summary matrix,

(V_{P}S_{P})^{T}CT(V_{P}S_{P})=U*S*U^{T}

which yields a rotation matrix:

R=V_{P}S_{P}⁻¹U

Then the orthogonalized scores and loadings are as follows:

P₀=PR

T₀=T(R^{T})⁻¹

This rotation matrix makes sure that:

TP^{T}=T₀P₀^{T}

Consequently, the cross product sum and sum of rows of scores are updated as follows:

CT=(R)⁻¹ CT(R^{T})⁻¹

sT=sT(R^{T})⁻¹

In case where P_{w} is not the same as P, the reorthogonalization steps, which are explained above, is directly applied to the loading weights P_{w} instead of P, and the necessary transformation is applied on the loadings P such that TP^{T}=TₒPₒ^{T}. It implies that Pₒ=PR.

For the sake of better compression, only components that are significant remain in the model and the rest are removed. The significance of each component is measured by the amount of contribution that that component has in modeling the data. The number of chosen components is decided based on the degree of fidelity that the user has set, the maximum number of components or by selecting the optimal number of components.

After the model has been updated, all or some part of the modeled data may be transferred to be stored permanently and to be removed from the memory. The main reason is to reduce the load on the memory. Keeping all the data in the memory is not inconsistent with the invention. It may, however, not only deteriorate the computation performance, but in long-running processes it might also cause the computer to run out of memory. In fact, a substantial achievement of the invention is that it does not need to have access to the past data in order to process a stream of data; it only needs the history parameters such as sT, and CT. Storing the modeled data makes it possible to restore earlier versions of the model and therefore to reconstruct an approximation of any part of the data at any time. The stored data includes the required materials for reconstructing: scores, loadings, translation vector, scales vector, rotation.

The process described above creates a bilinear model comprising a matrix of loading vectors P and a matrix of score vectors T, where the score vectors are the result of projection of an input block, or input frame, on the loading vectors. The set of input data increases in size because new input frames, or blocks of one or more frames, of data are received from the data generating process at points in time. It should be noted that the input frames or blocks do not have to be strictly associated with time, and may instead be associated with points along some other axis. For convenience this description will refer to points in time, but that is intended to cover other alternatives. As such, when the present disclosure, including the claims, refers to a point in time, that point in time may be an actual point in time at which a data generating process was sampled or sensors delivered sensor output, but it may also be interpreted indirectly as a point in time at which a condition or state in the data generating process was present, a point in time when a system according to the invention received input data, etc.

The combination of one loading vector and one score vector comprise a factor. Input blocks can be reconstructed for one reconstruction point in time by, for each factor, multiplying the loading vector and one element of the score vector corresponding to the reconstruction point in time and thereby forming a factor contribution. When all factor contributions are added together the result is an approximation of the input block. Whether this approximation is interpreted as a decompression, a reconstruction or an estimate may depend on the use case and whether additional manipulation of the data has been performed.

As described above, the model may occasionally be updated, and this update may be received from an encoder in the form of a transform packet. A transform packet may include one or more of the following: a transform matrix representing an affine transform from an earlier point in time to a later point in time, one or more new loading vectors, a re-centering vector, and a re-weighting vector. The affine transform will be described in further detail below. A typical case of affine transformation is rotation of loadings and scores to optimize covariance or co-occurrence properties.

In some embodiments of the invention a data encoder performs the method of generating and updating the model. The resulting model, including loading vectors, and score vectors, may be stored may be stored on a storage medium or transmitted through a transmission channel. The transform packets and any other generated data that has already been discussed, such as preprocessing parameters, re-centering vector, re-weighting vector and any other relevant data or parameters may also be stored or transmitted. A decoder may operate separate in time or space from the encoder to reconstruct the model based on the transform packet.

The decoder may be part of the same device as the encoder or part of a separate device.

In some embodiments the invention may store some information regarding the outlier along with the reconstruction components. In such case, a repository of outliers is considerd in analyses of the outlier objects outside the main body of the invention. As such, the outlier frames may be represented outside of the bilinear model, for example in a second-order repository. The outliers may be thoroughly studied in order to improve our understanding of the system. In cases where some objects follow a systematic pattern, they can be used either to improve the model or they may be used for predictive purposes.

The model components may be subjected to compression or source coding before transmission in order to further the resources required to store the data. Depending on the type of input data different compression methods can be used, for example MP3 for audio data, MPEG4 for video, and JPEG for image. The decompressed version of the compressed data (loadings P_{c}) may be used to replace the model data (loadings P) in order to order to make sure that both reconstruction and modeling parts are functioning on the same data. In case of lossy compression P_{c} won't be exactly the same as P. If there is a systematic error Pₑᵣᵣₒᵣ (P_{c} P+Pₑᵣᵣₒᵣ), when the model dimension corresponding to this systematically erroneous loading is used in subsequent score estimations, the scores for this model dimensions will be slightly wrong, while systematic “shadows” of the error vector Pₑᵣᵣₒᵣ will be present in the corresponding unmodeled residuals that are passed to the repository. Since it is systematic, it will be seen repeatedly and therefore distinguished from random noise in the decompositioning of the repository residuals and finally accepted as a new component (P_{new}). When the old, erroneous loadings P_{c} and the new “shadow” loading P_{new} and their corresponding scores are submitted to the reorthogonalization, they will be recombined into a component that is closer to the true one.

Repository can be a fixed or variable size container for the modeling residuals. As mentioned in the preceding paragraph, some part of modeled data might be removed from the memory. In such case, the corresponding residuals in the repository should also be removed.

At any stage of the modeling, it is possible to use the components for monitoring purposes. The loadings and scores not only contain the essence of the data, by removing redundancies and non-significant or random structures from data, they also make it easier to find patterns in the data, which can be used for graphical interpretation as well as for automatic outlier- and anomaly detection, classification, and prediction of certain qualities or forecasting of future events or behaviour. For example if a combination of scores shows that one or several object lie far from any other individual object, or from the apparent population of other objects others, they might be outliers. If a combination of scores shows that one or several objects are getting close to a dangerous zone (dangerous subspaces can be obtained by including some prior knowledge of the systems or by including an expert's judgement into the modeling), this information can be used for fault or failure detection purposes.

Alongside the main body of the model development in some embodiments a classification, regression, or prediction model may be developed, which relies on the model components. For example in case of Principal Component Regression (PCR) for regressor Xᵢ and its corresponding regressand Yᵢ, the regressor is decomposed in the main model as

Xᵢ=TᵢP/diag(c_{0,i})+1*x_{0,i}

then these components are used for developing the regression part

Yᵢ=TᵢQ′

where

Qᵢ=(Tᵢ′Tᵢ)⁻¹Tᵢ′Yᵢ.

This linear modelling of Y from T based on Ordinary Least Squares (OLS) corresponds approximately to the conventional PCR estimator applied to the multiple linear model of Y from X. Alternative estimators, such as PLSR, Ridge regression, Lasso, Elastic Net etc, and weighted versions thereof, may be used instead.

So for predicting the regressand for a new regressor xⱼ, firstly the relevant score is obtained:

tⱼ=(xⱼ−1*x_{0,i})*diag(c_{0,i})P(P′P)⁻¹

then the regressand is predicted as

yⱼtⱼQᵢ′.

Nonlinear models for prediction Y from T, e.g. using polynomial, nominal or ordinal extensions of T, or logistic functions of Y, may likewise be used. For statistically stable prediction, it is necessary the the scores Tᵢ are obtained on a large number of input and preferably the whole input from beginning till now. Keeping the whole scores in the memory neither is convenient nor it is necessary. The invention only keeps Tᵢ′Tᵢ and Tᵢ′Yᵢ in the memory, which are small matrices. Hence, external variables are thus linked to the model. Qualitative or quantitative characteristics (e.g. type of innovation, type or problem, quality of situation) may be represented as numerical or binary variables and given explicit values for some of the objects (e.g. 1), with other objects then implicitly or explicitly given other values (e.g. 0). Such external variables may be used for prediction/discrimination. The corresponding prediction or discrimination model or models for such external variables may be estimated e.g.by their regression on T for relevant subsets of objects. These estimated models may then be used for prediction of the external variables for other objects.

Separate clusters/classes modelled: Another way to introduce external information is to model different local structures separately: Clusters of objects (e.g. time points) discovered, either manually (by graphical inspection of the T-space), automatically (cluster analysis etc in T-space and residual summaries) or based on external variables, may be given separate interpretation descriptions (quantitative, verbal or pictoral) and submitted to dedicated, local models.

The model components (scores and loadings) may be subjected to further post-processing. Due to the fact that redundancies, outliers, and noise are removed in the model components and because of orthogonality of the these components, they are well-suited for further processing such as Independent Component Analysis (ICA), Multivariate Curve Resolution (MCR), Parafac, N-PLS etc, to search for simple structure or other desired characteristics, in the T-space and/or in the P (or Px) space. This may e.g. be implemented as a post-processing, to convert the abstract PCA-like, more or less orthogonal score- and loading spaces into non-orthogonal spaces with more meaningful interpretation, such as individual dimensions representing individual causal phenomena.

In some embodiments based on prior knowledge that is provided with the input data, it might be more convenient to split the data variables prior to modelling rather than modelling them as a unit. For example if two groups of sensors measure two uncorrelated phenomena, it might be computationally more convenient to model them separately and merge them in the end if needed. This type of splitting can be done in the preprocessing stage.

Another more interesting type of splitting occurs when an automated segmentation, which can be unsupervised clustering or supervised segmentation, is embedded alongside the main body of the modeling. In such cases, the model for each cluster or segment can be separated from the others for further analysis. The invention uses prior knowledge to find segments in the model components and develops a representation for each segment and improves it through the modeling when more data or knowledge is provided. In case no or inadequate prior knowledge is provided, the invention find clusters in the model components and improve them through the modeling process.

It is possible to merge different models. In some embodiments, there are different models developed for a system or for different systems that belong to the same category or there might exist several segments that represent the same type of phenomenon. In any case merging different models is consistent with the invention. After merging, the invention develops a model with redundancies and insignificant or random structures removed.

The stored data is used to reconstruct the approximation of input data for a given time horizon at any time. An important aspect of the invention is that it does not need the whole loadings to reconstruct the data; instead it only stores new loadings and provides means for reconstructing the old loadings and bringing them to the current coordination. However, for precautionary reasons and for computational efficiency, there are situations that the whole loadings, including the old and the new ones, are stored. These are referred to as entry points.

To reconstruct data belonging to a given time horizon, decoder loads the stored packets related to the time horizon. Within each packet an entry reference is provided, which points to the closest entry point. This entry point packet contains the required loadings that the transformation starts on them. For packet #i, where i={k, . . . ,k+m} let Pᵢ, T-₁, R₁, x_{0,i}, and c_{0,i} be the related components for the packets in the time horizon. Each of these packets contains the necessary components for reconstructing a portion of the time horizon, and concatenation of the reconstructed data for these packets will reconstruct for the whole time horizon.

At an entry point the stored data contains all necessary components (Pₖ, T-ₖ, x_{0,k}, c_{0,k}) in order for reconstruction:

Xₖ=T-ₖPₖ^{T}/diag(c_{0,k}) +1*x_{0,k}

But for a non-entry point case, the whole loadings are not available and only the new loadings at the time of storing are available directly. The remaining loadings are obtained by a linear transformation on the loadings that are stored previously. This transformation starts from an entry point and gradually increments to build the lacking loadings. Let Pᵢ, Tᵢ, R₁, xᵢ, and cᵢ be the components for the entry point with i=0, and for the subsequent packets with i={1, . . . ,k}.

P_{t,i+1}=[P_{t,i}*diag(cᵢ₊ᵢ/cᵢ), Pᵢ₊₁]*Rᵢ₊ᵢ, i={0, . . . , k−1}.

where P_{t,i+1} is the total incremented loadings at packet i+1, and P_{t,i}=P₀.

This affine transform is used to map between two different vector spaces corresponding to different time. A special use of this transformation is for analysis purposes. The invention uses the scores to develop clusters, segments and/or templates representing different phenomena in the data at one or several reference vector spaces. The affine transform can be used to transform the scores in any other time (vector space) to one of these reference vector spaces, and to assign each score to the templates and updating them or to create a new template for a new phenomenon. Another possibility is to transform these templates to the new vector space as the modeling process goes on, in other words keeping the reference templates always up-to-date with respect to the new vector space. Then comparing the new scores with these updated templates either to be assigned to one or several of the template and updating them or to create a new one.

The reconstruction at packet k is as follows:

Xₖ=T-ₖ P_{t,k}^{T}/diag(c_{0,k})+1*x_{0,k}.

The reconstructed data for the whole horizon is obtained by concatenating the reconstructed data for each of the packets in the horizon. Therefore, it is possible to reconstruct the data associated with any time prior to the reconstruction time.

The score matrix T not only summarizes the original input data on the loadings coordination, it gives an insight into the data, which is useful for better understanding the data, detecting outliers, and for designing classification and prediction methods. The invention makes it possible to map the scores associated with any time to coordination in another time. As a result, time development of the data can be investigated for further analysis purposes.

Let us say the scores in packet 1 are going to be mapped to the vector space of packet 2. In this case scores of packet 1 in the vector space of packet 2, T_{1|2}, are obtained as follows.

T_{1|2}=[T₁ 0]*(R₂^{T})⁻1*t-_{add}

dx₀=x_{0,1}−x_{0,2}

dx₀=dx₀*c_{0,2}

t_{add}=dx₀*(P₂^{T} P₂)⁻¹ P₂T

These equations provide an affine transform that maps the scores in packet 1 to the vector space of packet 2. t-_{add} is the vector resulting from standardizing the data with different centering. In general, in order to bring the scores in packet #k to the vector space of packet #k+m, the following recursive formula is used.

T_{i|i+1}=[T_{1-1|i} 0]*(Rᵢ₊₁^{T})⁻+1*t-_{add}

dx₀=x_{0,i}−x_{0,i+1}

dx₀=dx₀*c_{0,i+1}

t_{add}=dx₀*(Pᵢ₊₁^{T} Pᵢ₊₁)⁻¹ Pᵢ₊₁^{T}

where T_{k-1|k}=Tₖ, and T_{k+m-l|k+m} is the mapped version of the scores in packet #k to the vector space of packet #k+m. It should be noted that by inverting the affine transform it is possible to transform scores to preceding vector space.

Inputs objects: The objects (rows) represented by the input data may represent a long stream of related records (e.g. a database of many measured spectra from the same physical system, many images or related nature or many sound recordings from related situations), sampled discretely or (preferably) as a more or less continuous, high-dimensional data stream—a multichannel time series.

Input variables: The invention can be applied for any multichannel data stream, as long as each channel (variable) describes a more or less well defined information type (source, property or attribute). Three main types of input variables are particularly important: repeated spectral profiles, repeated spatial images or repeated temporal behaviors, and combinations thereof.

Repeated spectral profiles: The input channels represent a certain kind of profile of a system's properties. Example from chemistry and physics: multichannel atomic or molecular vibration spectra at different wavelengths in e.g. the X-ray, UV, visible-range, NIR, IR, microwave or radiowave range, Raman spectra, fluorescence spectra, NMR spectra, Mass spectra, chromatograms etc. Examples from biology: profiles of metabolic, transcriptional or genomic nature. Examples from economy, sociology, psychology, linguistics: Stock exchange profiles, financial transaction profiles, consumers' behavior profiles, expert sensory descriptive profiles, grammatical and word-profiles of texts. Examples from mechanical engineering: charges, temperatures, forces and deflections in physical structures, measured by two or more sensors, e.g. thermometers, pressure sensors, accelerometers, ampere-meters, voltmeters or any process sensors. Example of domain-transforms of time series data: Effect- and/or phase spectra (spectrograms) from repeated Fourier transforms of individual time series from e.g. temperature- or pressure measurements, motion recordings, economical indicators, optionally after pitch-estimation and -correction. Examples of image or sound summaries: spectral features of individual pixels in hyperspectral video; intensity profiles of multi-source vibration- or sound recordings. High-dimensional profiles of information content in series of images, obtained by a whole battery of spatial and/or temporal processes, e.g. gray-level histograms and texture profiles. Examples from computer science: Traffic profiles in networks and computers. Examples from computer simulations: Output profiles from multi-output mathematical models in computer simulations repeated under different conditions. Example from repeated or combined use of several data driven models, e.g. of the current invention: Inputs=outputs from other data generation models. The profiles may be submitted to generic or domain-specific preprocessing to optimize data properties e.g. wrt signal/noise, linear additivity, and the preprocessing parameter estimates may be used as part of the subsequent data input stream.

Repeated spatial images: Examples of 2D image sequences and video: Time series from heat sensitive camera and from black/white (e.g. night vision -) video, or from individual channels in single-or multichannel cameras, including hyperspectral video cameras. Example of 2D/3D sequences and—“video”: ultrasound, MRI, X-ray /CT, PET, e.g.repeatedly measured for cancer patients under active surveillance. Temporally resolved medical imaging (e.g. diffusion-based MRI). The image series may be submitted to generic or domain-specific preprocessing to optimize data properties, as described above. In particular, “stiff” and “soft” motions in video, medical images etc may be estimated (e.g. in terms of 1D, 2D or 3D optical flow) and compensated for (“image registration”); in that case both the motion fields and the motion-corrected images may be used as input to the current invention (so-called IDLE-modelling (ref Martens 2015).

Repeated temporal behaviors: A beating heart and a rotating machine represent more or less cyclic processes, where each cycle may be described as repetition in a 360 degrees polar coordinate system, resampled at some chosen angular pattern to form input comparable input vectors. Temporal pattern recognition may be used to remove phase variations.

Combinations of input types: Hence, The invention can be used for one dimensional data, where an input row corresponds to one set of measurement values or similar. The invention can also be used for two dimensional input, e.g. input from a camera. In this case the two dimensional image is processed as if it were one long one-dimensional vector. Yet the results can be presented in two dimensions. E.g., for human inspection, each loading can be inspected as a two dimensional image, and the same applies for center and scaling vectors; each can be shown as a two dimensional image. Hence, in series of multichannel spatial input data, e.g. RGB -and hyperspectral video streams, multi-modal MRI images, multichannel radar or lidar images, the 2- or higher-way input data from each time point may be unfolded into a very high-dimensional 1D vector (e.g. channels×pixels). In this case, the estimation of each new model loading in P and/or Px may (optionally) be refined by refolding into a 2D matrix, and subjecting it to low-rank bilinear approximation etc. (e.g. singular value decomposition, followed by e.g. rank 1 reconstruction, before unfolding the reconstruction back into 1-way vector format again, followed by suitable reorthogonalization and rescaling to length l). This bilinear filtering of the loadings can give statistically more stable data models. And the 2D reconstruction can give stronger compression than the original 1D loading vectors.

Conversely, such N-way input data streams may instead be unfolded row-wise instead of column-wise, so that each point in time, i, originally represented e.g. by Ni pixels×K channels in the input data for a set of nTimes time points of hyperspectral video, is unfolded in the spatiotemporal domain, yielding corresponding 1D score vector segments of length (nTimes×Ni pixels). Each such 1 D score vector segment may be refolded to yield a 2D nTime×Ni matrix, refined by low-rank approximation and again unfolded into a 1-way score vector segment. This bilinear filtering of the scores can likewise give more stable data models with stronger compression.

The present invention may be used as a part of an alarm system. The input to the invention could be sensors indicating the state of a system to be monitored. This could be frequencies of sound, camera input, chemical sensors, electrical sensors or similar. The invention will generate loadings and scores indicating the state of the system. There will typically be an initial learning phase when normal operation or normal states of the system, and then the alarm function will be enabled. An alarm can then be raised depending on changes in the system:
An alarm can be raised when a new factor is detected and has a power above some specified threshold. This will correspond to a new phenomenon appearing in the system to be monitored.
An alarm can be raised when the residual exceeds a given threshold. This would correspond to some phenomenon that will not fit into the model.
An alarm can be raised if a time-series forecasting of the model's state variables (the scores and/or the residual variance) indicates that the process state is moving in an undesired way or the data quality is deteriorating.
In the learning phase the system can store each combination of score values for each point in time. During the normal operation phase, for each point in time the system can check if the new combination of score values is close to a stored combination of score values. If so this indicates that the system is in a normal state. Otherwise, this is an unknown state of the system and an alarm can be raised. A human operator can check the alarm, and give feedback to the system: Either the situation is to be considered as normal, so that the score combination can be included in the set of normal states, or the situation can be considered as an alarm state, in which case the score combination can be recorded together with a classifier or description for the alarm.
Score combinations may be rotated to a common point in time.
In case the system is used for prediction of a value that can also be measured, the system can raise an alarm when a measured value deviates significantly from a prediction for the same value. For example, a prediction model can be built where internal temperature in an engine is predicted based on engine load, fuel type, environment temperature, air pressure and so on. As long as the measured value for internal temperature fits with a prediction for internal temperature, this would be considered a normal state, otherwise an alarm could be raised.
The system could be made to calibrate for an alarm condition. E.g., for an engine to be monitored, a calibration model (i.e. prediction model) can be built to predict wear of the piston rings based on running time, engine load, fuel type, vibration patterns and so on. When the prediction value reaches a threshold, this can be used to raise an alarm indicating that the piston rings should be renewed.
A method for predicting values of target variables that are known for certain points in time called training points and unknown for other points in time called prediction points, and where other variables are continually known, may be based on a bilinear model of the continually known variables. The model may be built as already described, and a prediction model may be trained based on the training points. Predictions for the target variables at prediction points can be estimated based on the prediction model.

The invention can be used for compressed, efficient transmission of data files between two sites, called sender and receiver site. At the sender side a data file can be modelled using the invention, resulting in loadings, scores and so on being computed. These can then be transmitted through a transmission channel. At the receiver side, the loadings, scores and so on may be used to reconstruct an approximation of the data file.

Equivalently, the invention can also be used for compressed, efficient storage and retrieval of data files. During storage the system could perform the same operations as for sending mentioned above, the model center, scaling, loadings, scores and so on can be stored (along with preprocessing states). Then, during retrieval, a reconstruction of the data can be made as specified for the receiver mentioned above.

In the compressed transmission or storage mentioned above, the compression arises from similar structures in the data becoming represented by a low number of factors. Yet, further compression is possible, in that the loadings, scores and so on can themselves be compressed using traditional compression tools. E.g., loadings, scores and so on may be compressed using transform coding like JPEG coding (for two-dimensional input) or wavelet coding, or quantization followed by Huffman coding, arithmetic coding, Lempel-Ziv coding or similar.

Transform packets may also be compressed. In some embodiments at least one part of one transform packet is compressed using a data compression technique.

In embodiments where a lossy compression technique is used, at least one transform packet may become a changed packet and the changed packet may be fed back to the encoder thus replacing the corresponding original part of the model.

Self correcting and progressive fidelity: In the case that a lossy compression method is used for loadings, scores and so on, leading to compression artifacts, all reconstructions will based on the compressed loadings, scores and so on. Compression (e.g. quantization) errors in the model center and loadings will cause small, but systematic errors in the data approximation. Likewise, effects of measurement noise and other types of errors in the input data will also cause small, but systematic errors in the data approximation. When residuals are submitted to the encoder repository, these errors will appear as many versions of the same small but systematic errors. Such systematic errors may be discovered and described as new PCs in the repository, and thus automatically corrected for in the modelling process.

Compression at fixed rate In some cases a fixed rate compression is wanted, where a data set is to be transmitted at a fixed bit rate. This means that a data set may be represented at different fidelities at different times. In this case, both the number of factors and the fidelity of transmission of each factor may be lowered to adapt to a limitation in bit rate. If the complexity of the data goes down later, the self correcting feature of the system as mentioned above will automatically correct for the systematic errors.

The invention may be used for different purposes depending on application. Compression is an intrinsic outcome of the invention, meaning that the stored data is of reduced size with respect to the raw input data. Prediction, clustering, and segmentation are other applications of the invention; in some embodiments based on additional knowledge of the system and/or similarities between the objects, the invention develops templates representing different segments/clusters of objects and improves them throughout the modeling process. For example for clustering/segmentation purposes a variety of clustering methods can be applied on the scores, e.g. Simca analysis, K-means, fuzzy clustering, or graph-based segmentation. The clustering/segmentation method provides a template for each of the clusters/segments, these templates are subjected to the affine transform and the trimming throughout the model processing, and are extended when more input data or external information is provided.

System monitoring is a general application of the invention, in which the goal is to monitor the operational states of a machine or process over time, and to detect and predict faults or failures in the system. The invention models the measured data from the system in term of components. Then based on the knowledge of the system, it detects outliers and anomalies, and develops templates for normal states of the operation as well as hazardous ones, and improves it over time. Doing so, it creates a comprehensive model for behaviour of the system, and it is able to predict the system going into dangerous operational zones and to raise alarms.

In some embodiments at least one score is used for automatically controlling a process.

A number of additional modifications may be made to the various embodiments of the invention. For example, at least one factor may be deleted based on a criterion associated with at least one of relevance, size, recency and memory availability.

In some embodiments the scores are calculated based on loading weights.

The two-way model comprising loadings and scores can be modified into a three way model, such as nPLS or PARAFAC.

In some embodiments loadings and scores are combined in a non-linear way to provide a reconstruction.

The loadings and scores can be postprocessed according to one or more of such criteria as Independent Component Analysis (ICA), Multivariate Curve Resolution (MCR), and Optimization of entropy properties, non-negativity or unimodality.

In some embodiments scores from two or more models are used as input blocks for another model.

In embodiments where two or more bi-linear models are used, for each input frame or set of input blocks a decision can be made regarding which model is to be updated based on each input block or set of input blocks. The decision may be made based on external measurements or metadata, clustering, or fit to each the model.

As already mentioned, the data generating process providing input data may include data from a wide range of sensors. For example, the input blocks may comprise physical measurements from a voltmeter, amperemeter, microphone, accelerometer, pressure sensor, RGB camera, thermal camera, hyper spectral camera, medical sensor, traffic sensor, magnetometer, gravimeter, chemical sensor or temperature sensor, or data originating from questionnaires, stock prices, word frequency counts in texts, statistical tables, medical measurements, data transmission measurements, production measurements or performance measurements.

Thus, those with skill in the art will realize that a data generating process is not limited to physical measurements that provide measurement data in real time. Also data that has already been collected and that is stored in a database is intended to fall under the definition of data from a data generating process as used herein.

While the invention has primarily been described in terms of the various processes and actions performed as part of a method, the invention also relates to devices and apparatuses that are configured to perform these methods. As such, an apparatus may include one or more processors, communication buses, working memory and persistent memory, data input and output interfaces, user input and output interfaces and all the other components that are typical for modern computing devices. Such an apparatus may be programmed or configured to perform the encoding processes associated with preprocessing, model generation and update, compression (the projection of an input vector on a loading matrix to generate a score vector), and buffering, storing or transmitting of the results. An apparatus may be similarly programmed or configured to perform the decoding processes associated with receipt or retrieval of the model, receipt of transform packets, update of the model, decompression, prediction, control or monitoring based on the model, as well as generation of audio, video or other output that may be understood or interpreted by a user. For example, one or more of loadings, scores, center, weights, residuals or predictions may be presented for a human operator or used in automatic control of a system.

In general, all process steps and activities described herein as part of a method may also be understood as a features provided by a device and a suitable hardware and software combination.

Instructions enabling a processor to perform the various methods of the invention may be stored on a computer readable medium.

### LIST OF VARIABLES

K number of input channels

k an individual input channel, k=1,2, . . . ,K

N number of samples

i an individual sample, i=1,2, . . . ,N

N_{b} number of samples in a block

L chosen degree of acceptable accuracy (explained variance)

A number of dimensions in sub-space, A<K

a an individual sub-space dimension, or “direction”

J number of known analyte patterns

P transformation matrix, or compression matrix, or loading matrix

pₐ the profile, or difference spectrum, or direction of dimension a (a row in P)

Z_{b} a block of input vectors

z₁ an input vector (a sample)

yᵢ linearized input vector

Y a block of linearized input vectors

S constituent spectra in a linear mixture model

nS number of constituent spectra in a mixture model

Further, the disclosure of this invention includes the following aspects, and the applicant reserves the right to claim one or more of the aspects as follows:

A. A method for compression of multidimensional data, comprising:

receiving a sequence of multidimensional input data;

compressing the received input data by
preprocessing sequential blocks of the input data;
compressing each preprocessed block of input data;
calculating a residual representing the difference between the preprocessed data block and the compressed data block;
storing the calculated residual in a repository of residuals;
outputting the compressed data; and

at certain intervals, extending the compression model by
analyzing the repository of residuals to detect significant patterns;
if a significant pattern is found, including the pattern in the compression model.

B. A method according to aspect A, wherein the intervals are predetermined regular time intervals.

C. A method according to aspect A, wherein the intervals are determined based on an evaluation of at least one of the size and the variance of the repository of residuals.

D. A method according to one of the previous aspects, wherein detection of significant patterns is done by performing principal component analysis (PCA) on the data in the repository.

E. A method according to aspect D, wherein PCA is performed by entering the values in the repository in a matrix and subjecting the matrix to singular value decomposition (SVD).

F. A method according to any one of the previous aspects, wherein inclusion of a detected significant pattern is included in the compression model by:
adding a new loading to the compression model; and
adding a new score to the compressed output data.

G. A method according to aspect F, further comprising:
after one or more new loadings have been added to the compression model, updating the compression model by performing one or more of recentering, reweighting and reorthogonalization.

H. A method according to any one of the previous aspects, further comprising:
after one or more new loadings have been added to the compression model, refining the compression model by removing loadings that are no longer considered significant.

I. A method according to any one of the previous aspects, wherein the multidimensional data is received from a plurality of sensors.

J. A method according to aspect H, wherein the plurality of sensors is chosen from the group consisting of: spectrometers, hyperspectral cameras, infrared cameras, ultrasound sensors, microphone arrays, antenna arrays, radio telescope arrays and thermometers.

K. A method according to any one of the aspects A-H, wherein the multidimensional data is a received from a repository of aggregated multidimensional data.

L. A method according to aspect K, wherein the repository of aggregated data is a repository of computer simulation results, social survey results, economical data and data extracted from network analysis.

M. A method for constructing and maintaining a bi-linear model of a set of frames of input data that is increasing in size,
the increasing being caused by new frames of data being included into the set of frames of input data at points in time,
the bi-linear model comprising score vectors and loading vectors, with one loading vector and one score vector together comprising a factor,
where forming reconstruction of the data for one reconstruction point in time comprises the steps of
   for each factor,
      multiplying together the loading vector and one element of the score vector corresponding to the reconstruction point in time thereby forming a factor contribution, and
      adding together all factor contributions,
wherein
   the bi-linear model is being updated based on transform packets formed by an encoder,
   each the transform packet comprising
      a transform matrix representing an affine transform from an earlier point in time to a later point in time, and

a plurality of new loading vectors.

N. The method of aspect M, wherein

the bi-linear model further comprises forming of the reconstruction further comprises adding a center vector.

O. A method for constructing and maintaining a bi-linear model of a set of input data that is increasing in size,
the increasing being caused by new frames of data being included into the input data set at points in time,
the bi-linear model comprising score vectors and loading vectors, with one loading vector and one score vector together comprising a factor,
where a reconstruction of the data for one reconstruction point in time can be made by
   for each factor, multiplying together the loading vector and one element of the score vector corresponding to the reconstruction point in time thereby forming a factor contribution,
   adding together all factor contributions,

wherein
the bi-linear model is being updated based on transform packets formed by an encoder,

each the transform packet comprising a re-centering vector.

P. A method for constructing and maintaining a bi-linear model of a set of input data that is increasing in size,
the increasing being caused by new frames of data being included into the input data set at points in time,
the bi-linear model comprising score vectors and loading vectors, with one loading vector and one score vector together comprising a factor,
where a reconstruction of the data for one reconstruction point in time can be made by
   for each factor, multiplying together the loading vector and one element of the score vector corresponding to the reconstruction point in time thereby forming a factor contribution,
   adding together all factor contributions,
wherein
   the bi-linear model is being updated based on transform packets formed by an encoder,

each the transform packet comprising a re-weighting vector.

Q. The method according to any of aspect M to P,

wherein
the encoder comprises a repository of more than one residual frames,
each residual frame being formed as the difference between an input frame and a reconstruction of the input frame using the bi-linear model, and the transform packet is based on statistical analysis of the repository.

R. The method according to aspect Q, wherein the repository comprises one least recent part comprising the least recent residual frames and one most recent part comprising the most recent residual frames, and

wherein loadings are based on both the parts while scores are based on the least recent part.

S. The method of aspect R, wherein preliminary scores are provided for the most recent part.T. The method according to any one of aspect Q to U, wherein outlier frames are detected using leverage or residual variance in the statistical analysis.U. The method of aspect T, wherein the outlier frames are represented outside of the bi-linear model. V. The method of aspect T, wherein the outlier frames are modeled in a second-order repository.

W. The method of any one of aspects P to V, wherein the loadings and scores are rotated to optimize covariance or co-occurrence properties.

X. The method of any one of aspects M to W, wherein at least one of the factors can be deleted based on a criterion based on at least one of relevance, size, recency or memory availability.

Y. The method of any one of aspects M to X, wherein the scores are calculated based on loading weights.

Z. The method of any of aspects M to Y, wherein the two-way model comprising loadings and scores is modified into a three way model, such as nPLS or PARAFAC.

AA. The method of any of aspects M to Z, wherein loadings and scores are combined in a non-linear way to provide a reconstruction.

BB. The method of any one of aspects from M to AA, wherein the loadings and scores are postprocessed according to one or more of these criteria:
1) Independent Component Analysis (ICA),
2) Multivariate Curve Resolution (MCR), or
3) Optimization of entropy properties, non-negativity or unimodality.

CC. The method of any one of aspects M to BB, wherein at least one score is used for automatically controlling a process.

DD. A data encoder using the method of any of aspects M to CC for constructing a bi-linear model, wherein
the transform packets are stored on a storage medium or transmitted through a transmission channel, and

a decoder separate in time or space from the encoder reconstructs the model based on the transform packet.

EE. An encoded signal produced by the method of any one of aspects M to CC or the apparatus of aspect DD.

FF. A computer readable storage medium containing a data structure produced by the method of any one of aspects M to CC or the apparatus of aspect DD.

1. A method for compressing, monitoring or analyzing multidimensional data in a computer system, comprising:
receiving a sequence of multidimensional input data from a data generating process;
processing the received input data by
using an approximation model to project respective blocks of input data on a subspace;
for each block of data, calculating a residual representing the difference between said data block and a reconstruction of said data block from the projection of the data block on said subspace;
storing the calculated residual in a repository of residuals;
appending the projection of the data block to previously stored projections of data blocks in an output buffer; and
at predefined intervals, extending the approximation model by
analyzing the repository of residuals to detect significant patterns;
if a significant pattern is found, including the pattern in the approximation model.

2. A method according to claim 1, wherein said intervals are one of predetermined regular time intervals, and based on an evaluation of at least one of the size and the variance of the repository of residuals.

3. A method according to claim 1, further comprising preprocessing including at least one of linearization, preliminary modeling and signal conditioning prior to the step of processing.

4. A method according to claim 1, wherein detection of significant patterns is done by performing at least one of principal component analysis (PCA) and singular value decomposition (SVD) on the data in the repository.

5. A method according to claim 1, wherein said approximation model and said projection on said subspace together constitute a bi-linear model where the approximation model is a matrix of loading vectors and the projection on said subspace is a score vector, with one loading vector and one score vector together comprising a factor.

6. A method according to claim 1, wherein a detected significant pattern is included in the approximation model by:
adding a new loading to the approximation model; and
distributing new score components to the previously stored projections of data blocks.

7. A method according to claim 6, further comprising:
after one or more new loadings have been added to the approximation model, updating the approximation model by performing one or more of recentering, reweighting and reorthogonalization.

8. A method according to claim 6, further comprising:
generating a transform packet comprising at least one of
a transform matrix representing an affine transform from an earlier point in time to a later point in time, and
at least one new loading vector;
a re-centering vector; and
a re-weighting vector.

9. A method according to claim 1, further comprising:
after one or more new loadings have been added to the approximation model, refining said approximation model by removing loadings that are no longer considered significant.

10. A method according to claim 1, wherein said multidimensional data is received from a plurality of sensors chosen from the group consisting of: spectrometers, hyperspectral cameras, infrared cameras, ultrasound sensors, microphone arrays, antenna arrays, radio telescope arrays and thermometers.

11. A method according to claim 1, wherein said multidimensional data is a received from a repository of aggregated multidimensional data.

12. A method according to claim 11, wherein said repository of aggregated data is a repository of computer simulation results, social survey results, economical data and data extracted from network analysis.

13. A method according to claim 1, wherein said projected data blocks stored in said output buffer is forwarded to a display on a computer system.

14. A method according to claim 1, wherein said projected data blocks stored in said output buffer is used to regenerate an approximation of the multidimensional input data.

15. A method according to claim 1, wherein said projected data blocks stored in said output buffer is analyzed to generate a representation or an estimate of a feature of said data generating process.

16. A method for maintaining a bi-linear model constructed from a set of blocks of input data received by an encoder from a data generating process, wherein said set of blocks is increasing in size as a result of repeated inclusion of additional blocks of input data received from said data generating process at points in time;
said bi-linear model comprising score vectors and loading vectors, with one loading vector and one score vector together comprising a factor;
wherein forming reconstruction of data from said data generating process for one reconstruction point in time comprises the steps of
for each factor,
multiplying together said loading vector and one element of said score vector corresponding to said reconstruction point in time thereby forming a factor contribution; and
adding together all factor contributions; and
wherein said bi-linear model is updated based on receipt of a transform packet from said encoder.

17. A method according to claim 16, wherein said transform packet comprises
a transform matrix representing an affine transform from an earlier point in time to a later point in time, and
a at least one new loading vector.

18. A method according to claim 16, wherein said bi-linear model further comprises a center vector.

19. A method according to claim 16, wherein said transform packets comprises a re-centering vector.

20. A method according to claim 16, wherein said transform packet comprises a re-weighting vector.

21. A method according to claim 16, wherein
said transform packet has been generated by said encoder from a repository of a plurality of residual blocks, wherein each residual block has been generated as the difference between an input block and a reconstruction of said input block using said bi-linear model; and
said transform packet includes at least a new loading vector generated from statistical analysis of said repository.

22. A method according to claim 21, wherein
said repository comprises one least recent part comprising the least recent residual blocks and one most recent part comprising the most recent residual blocks; and
wherein loadings are based on both said parts.

23. A method according to claim 21, wherein residuals to be included in the repository are selected or de-selected based on a criterion that can be one or more of the following:
a selected number of the latest residuals,
residuals that are statistically significant, and
residuals that have selected characteristics.

24. A method according to claim 21, wherein said statistical analysis comprises at least one of Principal Component Analysis and Singular Value Decomposition.

25. A method according to claim 16, wherein outlier blocks are detected using leverage or residual variance in said statistical analysis.

26. A method according to claim 25, wherein said outlier blocks are modeled in a second-order repository.

27. A method according to claim 16, wherein said loadings and scores are rotated to optimize covariance or co-occurrence properties.

28. A method according to claim 16, wherein at least one of said factors can be deleted based on a criterion based on at least one of relevance, size, recency or memory availability.

29. The method of claim 16, wherein said scores are calculated based on loading weights.

30. The method of claim 16, wherein the two-way model comprising loadings and scores is modified into a three way model, such as nPLS or PARAFAC.

31. The method of claim 16, wherein loadings and scores are combined in a non-linear way to provide a reconstruction.

32. The method of claim 16, wherein the loadings and scores are postprocessed according to one or more of these criteria:
1) Independent Component Analysis (ICA),
2) Multivariate Curve Resolution (MCR), or
3) Optimization of entropy properties, non-negativity or unimodality.

33. A method according to claim 16, wherein at least one score is used for automatically controlling a process.

34. A method according to claim 1, wherein at least one part of one transform packet is compressed using a data compression technique.

35. A method according to claim 34, wherein
said data compression technique is a lossy technique that makes at least one transform packet become a changed packed, and
said changed packet is fed back to said encoder thus replacing the corresponding original part of said model.

36. A method for monitoring the state of a system,
wherein a model is built according to claim 1,
wherein an alarm state is set based on score combinations that are not close to earlier observed score combinations, or residual variance exceeding a threshold.

37. A method according to claim 36, wherein score combinations are rotated to a common point in time.

38. A method for predicting values of target variables that are known for certain points in time called training points and unknown for other points in time called prediction points, while other variables are continually known,
wherein a bi-linear model of the continually known variables is built according to claim 1,
a prediction model is trained based on the training points, and
predictions for the target variables at prediction points are estimated based on said prediction model.

39. The method of claim 1, wherein scores from two or more models are used as input blocks for another model.

40. The method of claim 13,
wherein two or more bi-linear models are used,
for each input block or set of input blocks a decision is made regarding which model is to be updated based on each said input frame or set of input blocks, and
said decision being made based on external measurements or metadata, clustering, or fit to each said model.

41. The method according to claim 13, wherein said input blocks comprise physical measurements from a voltmeter, amperemeter, microphone, accelerometer, pressure sensor, RGB camera, thermal camera, hyper spectral camera, medical sensor, traffic sensor, magnetometer, gravimeter, chemical sensor or temperature sensor, or data originating from questionnaires, stock prices, word frequency counts in texts, statistical tables, medical measurements, data transmission measurements, production measurements or performance measurements.

42. A data encoder using the method of claim 1 for constructing a bi-linear model, wherein
the transform packets are stored on a storage medium or transmitted through a transmission channel, where it is accessible to a decoder separate in time or space from the encoder to reconstruct said model based on said transform packet.

43. A decoder using the method of claim 16 to reconstruct an approximation of input data from said data generating process based on said bilinear model and said transform packet.

44. An apparatus for constructing and maintaining a bi-linear model of a set of blocks of input data that is increasing in size,
said increasing being caused by new blocks of data being included into the set of blocks of input data at points in time,
said bi-linear model comprising score vectors and loading vectors, with one loading vector and one score vector together comprising a factor,
where a reconstruction of said data for one reconstruction point in time can be made by
for each factor, multiplying together said loading vector and one element of said score vector corresponding to said reconstruction point in time thereby forming a factor contribution, and
adding together all factor contributions,
wherein
said bi-linear model is being updated based on transform packets by an encoder,
each said transform packet comprising at least one of
a transform matrix representing an affine transform from an earlier point in time to a later point in time, and
a plurality of new loading vectors.

45. (canceled)

46. An apparatus according to claim 44, wherein one or more of loadings, scores, center, weights, residuals or predictions are used to generate a representation on a display.

47. The apparatus according to claim 44, wherein one or more of loadings, scores, center, weights or residuals are used in automatic control of a system.

48. An apparatus according to claim 47, wherein said apparatus is adapted to operate as a decoder configured to reconstruct the model at different points in time.

49. An apparatus according to claim 48, wherein said decoder is further configured to use the reconstructed model to reconstruct an approximation of the input data.

50. A computer readable medium carrying computer executable instructions capable of enabling a processor to perform any one of the methods according to claim 1.
